(19) United States
(12) Patent Application Publication
(10) Pub. No.: US 2022/0094341 A1
(43) Pub. Date: Mar. 24, 2022

(54) ACTIVE PULSE SHAPING TO CONTROL MULTIPLE QUBITS WITH A SHARED CHANNEL

(71) Applicant: Intel Corporation, Santa Clara, CA (US)

(72) Inventors: Stefano Pellerano, Beaverton, OR (US); Jeroen Petrus Gerardus van Dijk, 3527 DZ Utrecht (NL); Bishnu Patra, 2624ES Delft (NL); Masoud Babaie, 2642 KG (NL); Fabio Sebastiano, 2635MX Den Hoorn (IT); Edoardo Charbon, 1008 Jouxtens-Mezery (CH)

(73) Assignee: Intel Corporation, Santa Clara, CA (US)

(21) Appl. No.: 17/030,512

(22) Filed: Sep. 24, 2020

(51) Int. Cl. H03K 3/38; H01L 27/18; H01L 39/02; H01L 39/22; G06N 10/00

(52) U.S. Cl. CPC H03K 3/38; H01L 27/18; G06N 10/00; H01L 39/228; H01L 39/223; H01L 39/025

(57) ABSTRACT

Quantum circuit assemblies that employ active pulse shaping in order to be able to control states of a plurality of qubits with signal pulses propagated over a shared signal propagation channel are disclosed. An example quantum circuit assembly includes a quantum circuit component that includes a first qubit, associated with a first frequency to control the state of the first qubit, and a second qubit, associated with a second frequency to control the state of the second qubit. A shared transmission channel is coupled to the first and second qubits. The assembly further includes a signal pulse generation circuit, configured to generate a signal pulse to be propagated over the shared transmission channel to control the state of the first qubit, where the signal pulse has a center frequency at the first frequency, a bandwidth that includes the second frequency, and a notch at the second frequency.

### BACKGROUND

Quantum computing refers to the field of research related to computation systems that use quantum-mechanical phenomena to manipulate data. These quantum-mechanical phenomena, such as superposition (in which a quantum variable can simultaneously exist in multiple different states) and entanglement (in which multiple quantum variables have related states irrespective of the distance between them in space or time), do not have analogs in the world of classical computing, and thus cannot be implemented with classical computing devices.

Quantum computers use so-called quantum bits, referred to as qubits (both terms “bits” and “qubits” often interchangeably refer to the values that they hold as well as to the actual devices that store the values). Similar to a bit of a classical computer, at any given time, a qubit can be either 0 or 1. However, in contrast to a bit of a classical computer, a qubit can also be 0 and 1 at the same time, which is a result of superposition of quantum states—a uniquely quantum-mechanical phenomenon. Entanglement also contributes to the unique nature of qubits in that input data to a quantum processor can be spread out among entangled qubits, allowing manipulation of that data to be spread out as well: providing input data to one qubit results in that data being shared to other qubits with which the first qubit is entangled.

Compared to well-established and thoroughly researched classical computers, quantum computing is still in its infancy, with the highest number of qubits in a solid-state quantum processor currently being below 100. One of the main challenges to increasing the number of qubits resides in protecting qubits from decoherence so that they can stay in their information-holding states long enough to perform the necessary calculations and read out the results. For this reason, qubits are often operated at cryogenic temperatures, typically just a few degrees Kelvin or even just a few millikelvin above absolute zero, because at cryogenic temperatures thermal energy is low enough to not cause spurious excitations, which is thought to help minimize qubit decoherence. Providing signals to quantum circuit components with such qubits is not a trivial task and further improvements would be desirable.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1-3 are cross-sectional views of an example device implementing quantum dot qubits, according to some embodiments of the present disclosure.

FIGS. 4-6 are cross-sectional views of various examples of quantum well stacks that may be used in a quantum dot device, according to some embodiments of the present disclosure.

FIGS. 7-13 illustrate example base/fin arrangements that may be used in a quantum dot device, according to some embodiments of the present disclosure.

FIG. 14 provides a schematic illustration of an example device implementing superconducting qubits, according to some embodiments of the present disclosure.

FIG. 15 provides a schematic illustration of an example physical layout of a device implementing superconducting qubits, according to some embodiments of the present disclosure.

FIG. 16 provides a schematic illustration of a quantum circuit assembly configured to implement active pulse shaping to control multiple qubits with a shared transmission channel for providing signals to a quantum circuit component, according to some embodiments of the present disclosure.

FIG. 17 provides a flow diagram of a method for implementing active pulse shaping to control multiple qubits with a shared transmission channel, according to some embodiments of the present disclosure.

FIG. 18 provides an example illustration of power spectral density (PSD) as a function of frequency for a shaped pulse that may be used to control a given qubit by being provided over a channel shared with a plurality of other qubits, according to some embodiments of the present disclosure.

FIGS. 19A and 19B are top views of a wafer and dies that may include one or more of quantum circuit assemblies disclosed herein.

FIG. 20 is a cross-sectional side view of a device assembly that may include one or more of quantum circuit assemblies disclosed herein.

FIG. 21 is a block diagram of an example quantum computing device that may include one or more of quantum circuit assemblies disclosed herein, in accordance with various embodiments.

### DETAILED DESCRIPTION

### Overview

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating active pulse shaping to control multiple qubits with a shared transmission channel, proposed herein, it might be useful to first understand phenomena that may come into play in quantum computing systems. The following foundational information may be viewed as a basis from which the present disclosure may be properly explained. Such information is offered for purposes of explanation only and, accordingly, should not be construed in any way to limit the broad scope of the present disclosure and its potential applications.

As briefly described above, quantum computing, or quantum information processing, refers to the field of research related to computation systems that use quantum-mechanical phenomena to store and manipulate data. One example of quantum-mechanical phenomena is the principle of quantum superposition, which asserts that any two or more quantum states can be added together, i.e. superposed, to produce another valid quantum state, and that any quantum state can be represented as a sum of two or more other distinct states. Quantum entanglement is another example of quantum-mechanical phenomena. Entanglement refers to groups of particles or quantum bits being generated or made to interact in such a way that the state of one particle becomes intertwined with that of the others. Furthermore, the quantum state of each qubit cannot be described independently. Instead, the quantum state is given for the group of entangled particles as a whole. So for example, two entangled qubits are now represented by a superposition of 4 quantum states, and N entangled qubits are represented by a superposition of 2^{N} quantum states. Yet another example of quantum-mechanical phenomena is sometimes described as a “collapse” because it asserts that when we observe (measure) qubits, we unavoidably change their properties in that, once observed, the qubits cease to be in a state of superposition or entanglement (i.e. by trying to ascertain anything about the particles, we collapse their state) and collapse to one of the 2^{N} quantum states.

Put simply, superposition postulates that a given qubit can be simultaneously in two states; entanglement postulates that two qubits can be related in that they are able to instantly coordinate their states irrespective of the distance between them in space and time so as to exist in a superposition of 4 states or in the case of N qubits in a superposition of 2^{N} quantum states; and collapse postulates that when one observes a qubit, one unavoidably changes the state of the qubit and its entanglement with other qubits. These unique phenomena make manipulation of data in quantum computers significantly different from that of classical computers (i.e. computers that use phenomena of classical physics). Furthermore, as briefly described above, for the reason of protecting fragile qubits from decoherence, they are often operated at cryogenic temperatures by being placed in a suitable cooling apparatus, e.g. a dilution refrigerator. This raises challenges from accurate estimation and control of the temperatures to providing various signals to qubit devices which must be kept at such low temperatures.

None of the challenges described above ever had to be addressed for classical computers, and these challenges are not easy. In particular, providing signals to control (e.g., set) the states of various qubits is very challenging in view of short coherence times of qubits. As described above, a qubit may be in a state 0 or a state 1 or in any continuum of states in between state 0 and state 1. To excite a qubit to be in a particular state, a pulse signal of a specific center frequency, power and phase needs to be provided to the qubit. The center frequency may be, e.g., in the radio frequency (RF) spectrum or in the optical spectrum of electromagnetic radiation. The power of the signal may be used to define the state of the qubit. For example, higher power signals may be used to “flip” the qubit (i.e., change the state from 1 to 0), while lower power signals may be used to set the qubit to some kind of a superposition state. The signal may be provided over any suitable transmission channel, such as a designated communication line (e.g., an RF transmission line configured to support propagation of RF signal pulses or a waveguide configured to support propagation of optical pulses) or free space (i.e., free-space propagation is a kind of a channel over which signals may be provided to qubits).

In order to scale quantum circuit assemblies to include larger number of qubits in an efficient manner, it is desirable to be able to use a single channel for providing signals to control multiple qubits (i.e., to share a channel). To that end, frequency division multiplexing may be used in that different qubits may be associated with different center frequencies (i.e., different frequencies may be used to control the states of different qubits). For example, qubit q1 may be associated with a frequency f_{q1} to be used to control the state of qubit q1 (i.e., a signal pulse of frequency f_{q1} may be used to control qubit q1), while qubit q2 may be associated with a frequency f_{q2}, different from the frequency f_{q1}, to be used to control the state of qubit q2 (i.e., a signal pulse of frequency f_{q2} may be used to control qubit q2). A single channel configured to support propagation of signals at frequencies f_{q1} and f_{q2} may then be used to control these two qubits.

Ideally, a signal of frequency f_{q1}, intended to control qubit q1, will not affect the state of qubit q2 because qubit q2 is associated with a different frequency. However, in practice, a signal pulse of a given center frequency also has signal components at other frequencies (i.e., a signal pulse may have a certain bandwidth), with a power spectral density (PSD) function of the signal being such that the PSD is highest at the center frequency and gradually decreases at frequencies farther and farther away from the center frequency. Thus, it may happen that the bandwidth of the signal having the center frequency f_{q1}, intended to control qubit q1, may include components of non-negligible energy at the frequency f_{q2}, intended to control qubit q2. In this case, when a shared transmission channel is coupled to both qubits q1 and q2 and such a signal is propagated over the channel in order to control the state of qubit q1, it may also inadvertently change/disturb the state of qubit q2. Such a phenomenon is typically referred to as “crosstalk” and is very detrimental to qubit operation.

In order to reduce crosstalk, bandwidth of signal pulses used to control different qubits may be reduced, so that the signal pulses configured to control different qubits do not overlap in the frequency domain. However, bandwidth of a signal pulse is inversely proportional to pulse duration, which means that reducing the bandwidth increases the pulse duration. Increasing the pulse duration means that signal has to be pulsed slower and the time needed to set the state of a qubit may be unacceptably long in view of short coherence times of qubits. Thus, in order to operate qubits on time scales that are acceptable for short coherence times of qubits, pulses to set qubit states should be relatively short, but that increases their bandwidth and, therefore, crosstalk. Finding an optimal tradeoff between pulsing fast and acceptably low levels of crosstalk is difficult to achieve. Improved devices and methods for providing signals to quantum circuit components to control states of multiple qubits using a shared transmission channel are, therefore, imperative to for ensuring proper operation of the qubits.

Embodiments of the present disclosure provide quantum circuit assemblies that employ active (i.e., deliberate) pulse shaping in order to be able to control a plurality of qubits (e.g., to control states of multiple qubits) with signal pulses propagated over a shared signal propagation channel (i.e., a channel that is coupled to each of the plurality of qubits, also referred to herein simply as a “channel”). In one aspect of the present disclosure, an example quantum circuit assembly includes a quantum circuit component having a first qubit, associated with a first frequency to be used to control a state of the first qubit, and further having a second qubit, associated with a second frequency to be used to control a state of the second qubit. The assembly further includes a control line in a form of a shared signal propagation channel, configured to support propagation of signal pulses configured to control the states of the first and second qubits, and a signal pulse generation circuit, configured to generate a signal pulse to be propagated over the signal propagation channel to control the state of the first qubit. The signal pulse has a center frequency being substantially equal to the first frequency, a frequency bandwidth that includes the second frequency, and a notch (i.e., a distinct decrease in power spectral density) at a frequency substantially equal to the second frequency. When the shared transmission channel is used to control more than the first and second qubits, each of the further qubits being associated with a respective further, different frequency, the signal pulse used to control the first qubit may further include notches at frequencies substantially equal to frequencies associated with the further qubits. Active pulse shaping of a signal pulse for a first qubit by providing notches at frequencies corresponding to other qubits allows using a shared transmission channel for providing signal pulses of relatively wide bandwidth, thus enabling pulsing the signals fast enough to reduce the errors due to qubit decoherence of the first qubit on the overall quantum algorithm, while simultaneously reducing crosstalk with the other qubits.

In various embodiments, signal pulses that have been actively shaped to control different qubits may be provided over the shared transmission channel at different times (i.e., one signal pulse at a time) or at times that may at least partially or fully overlap with one another. Embodiments of the present disclosure allow a signal pulse for controlling qubit q1 to be shaped to have a notch at substantially the center frequency of qubit q2 and a signal pulse for controlling qubit q2 to be shaped to have a notch at substantially the center frequency of qubit q1. In this manner, effect of the signal pulse for qubit q1 on qubit q2 may be minimized, and vice versa. Advantageously, such signal pulses may share the same channel and may be propagated at the same time (i.e., the signal pulses for controlling different qubits may be superimposed onto one another) or at different times.

Some descriptions provided herein refer to the shared transmission channel being an RF transmission line. However, these descriptions are equally applicable to implementations of quantum circuit assemblies where the shared transmission channel is a shared communications line for propagating optical pulses or where the shared transmission channel is free space (either for RF or optical signals), all of which implementations being within the scope of the present disclosure. Furthermore, some descriptions provided herein refer to quantum dot qubits and to superconducting qubits, in particular to transmons, which is one class of superconducting qubits. However, these descriptions are equally applicable to implementations of quantum circuit assemblies configured to implement active pulse shaping to control any kind of qubits, e.g., to control superconducting qubits other than transmons and/or qubits other than superconducting qubits and quantum dot qubits, all of which implementations being within the scope of the present disclosure. Furthermore, in some embodiments, the quantum circuit components described herein may implement hybrid semiconducting-superconducting quantum circuits.

In various embodiments, quantum circuit assemblies configured to implement active pulse shaping to control multiple qubits with a shared transmission channel, e.g., with a shared RF transmission line, as described herein may be used to implement components associated with a quantum integrated circuit (IC). Such components may include those that are mounted on or embedded in a quantum IC, or those connected to a quantum IC. The quantum IC may be either analog or digital and may be used in a number of applications within or associated with quantum systems, such as e.g. quantum processors, quantum amplifiers, quantum sensors, etc., depending on the components associated with the IC. The IC may be employed as part of a chipset for executing one or more related functions in a quantum system.

In order to provide substantially lossless connectivity to, from, and between the qubits, some or all of the electrically conductive portions of quantum circuit assemblies described herein, in particular various RF transmission lines described herein, as well as other components of quantum circuits, may be made from one or more superconductive materials. However, some or all of these electrically conductive portions could be made from electrically conductive materials which are not superconductive. In the following, unless specified otherwise, reference to an electrically conductive material implies that a superconductive material can be used, and vice versa. Furthermore, materials described herein as “superconductive/superconducting materials” may refer to materials, including alloys of materials, that exhibit superconducting behavior at typical qubit operating conditions (e.g. materials which exhibit superconducting behavior at very low temperatures at which qubits typically operate), but which may or may not exhibit such behavior at higher temperatures (e.g. at room temperatures). Examples of such materials include aluminum (Al), niobium (Nb), niobium nitride (NbN), titanium nitride (TiN), niobium titanium nitride (NbTiN), indium (In), and molybdenum rhenium (MoRe), all of which are particular types of superconductors at qubit operating temperatures, as well as their alloys.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g. scanning electron microscopy (SEM) images or transmission electron microscope (TEM) images. In such images of real structures, possible processing defects could also be visible, such as e.g. not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

In the following detailed description, various aspects of the illustrative implementations will be described using terms commonly employed by those skilled in the art to convey the substance of their work to others skilled in the art. For example, the terms “oxide,” “carbide,” “nitride,” etc. refer to compounds containing, respectively, oxygen, carbon, nitrogen, etc. The terms “substantially,” “close,” “approximately,” “near,” and “about,” generally refer to being within +/−5-20% of a target value based on the context of a particular value as described herein or as known in the art. Similarly, terms indicating orientation of various elements, such as e.g. “coplanar,” “perpendicular,” “orthogonal,” “parallel,” or any other angle between the elements, generally refer to being within +/−5-20% of a target value based on the context of a particular value as described herein or as known in the art.

Furthermore, as used herein, terms indicating what may be considered an idealized behavior, such as e.g. “lossless” (or “low-loss”) or “superconductive/superconducting,” are intended to cover functionality that may not be exactly ideal but is within acceptable margins for a given application. For example, a certain level of loss, either in terms of nonzero electrical resistance or nonzero amount of spurious two-level systems (TLSs) may be acceptable such that the resulting materials and structures may still be referred to by these “idealized” terms. Specific values associated with an acceptable level of loss are expected to change over time as fabrication precision will improve and as fault-tolerant schemes may become more tolerant of higher losses, all of which are within the scope of the present disclosure.

Still further, while the present disclosure may include references to RF signals, in particular to microwave signals, this is done only because current qubits are designed to work with such signals because the energy in the microwave range is higher than thermal excitations at the temperature that qubits are typically operated at. In addition, techniques for the control and measurement of microwave signals are well known. For these reasons, typical frequencies of qubits are in 1-30 GHz, e.g. in 3-10 GHz range, in order to be higher than thermal excitations, but low enough for ease of microwave engineering. However, advantageously, because excitation energy of qubits is controlled by the circuit elements, qubits can be designed to have any frequency. Therefore, in general, qubits could be designed to operate with signals in other ranges of electromagnetic spectrum and embodiments of the present disclosure could be modified accordingly. All of these alternative implementations are within the scope of the present disclosure.

Active Pulse Shaping with Various Types of Qubits

As described above, the ability to manipulate and read out quantum states, making quantum-mechanical phenomena visible and traceable, and the ability to deal with and improve on the fragility of quantum states of a qubit present unique challenges not found in classical computers. These challenges explain why so many current efforts of the industry and the academics continue to focus on a search for new and improved physical systems whose functionality could approach that expected of theoretically designed qubits. Physical systems for implementing qubits that have been explored until now include e.g. semiconducting qubits including those made using quantum dots (e.g., spin qubits and charge qubits), superconducting qubits (e.g. flux qubits or transmon qubits, the latter sometimes simply referred to as “transmons”), photon polarization qubits, single trapped ion qubits, etc. To indicate that these devices implement qubits, sometimes these devices are referred to as qubits, e.g. quantum dot qubits, superconducting qubits, etc.

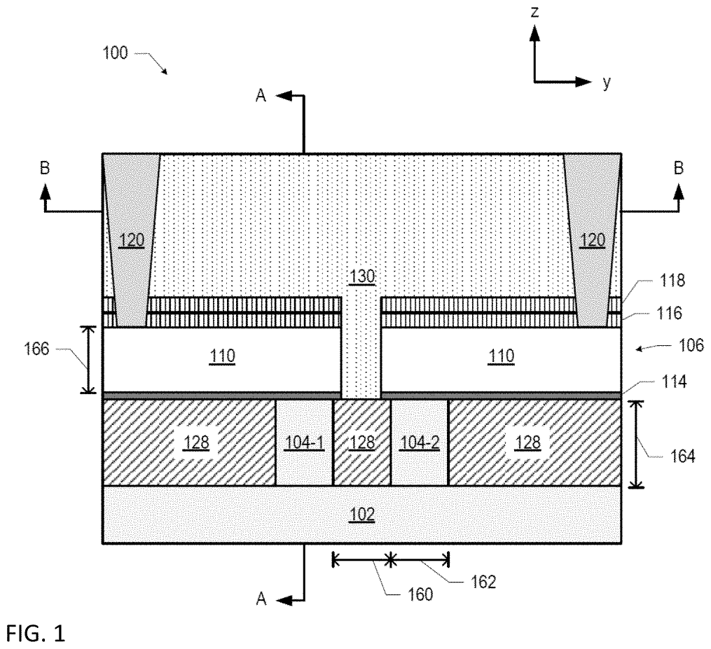

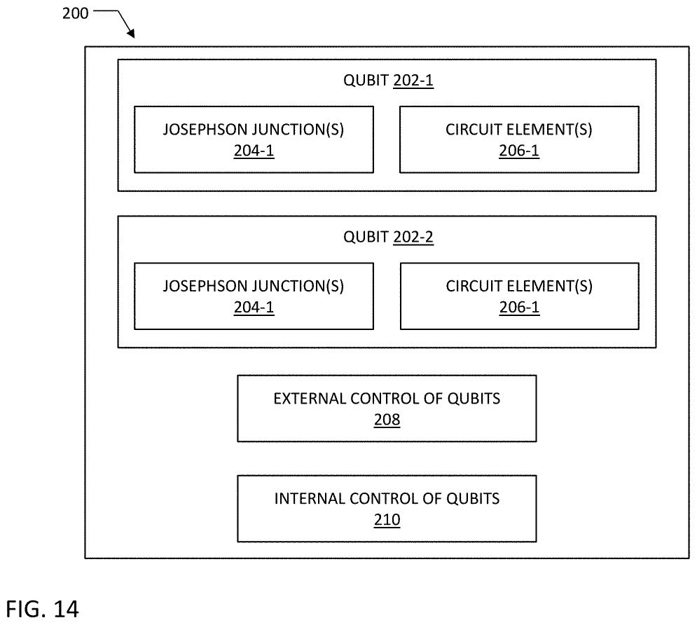

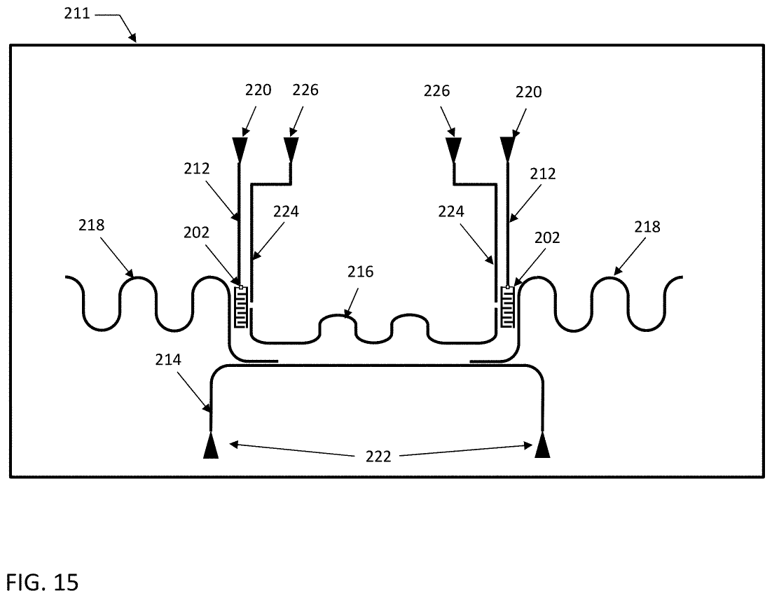

The type of qubits used in a quantum circuit component would affect what types of signals may benefit from active pulse shaping to control multiple qubits with a shared transmission channel, e.g., with a shared RF transmission line, as described herein. Below, two example quantum circuit components are described—one incorporating quantum dot qubits (FIGS. 1-13) and one incorporating superconducting qubits (FIGS. 14-15). However, active pulse shaping to control multiple qubits with a shared transmission channel as described herein is applicable to quantum circuit components that include any type of qubits, all of which are within the scope of the present disclosure.

Example Quantum Circuit Components with Quantum Dot Qubits

Quantum dot devices may enable the formation of quantum dots to serve as quantum bits (i.e. as qubits) in a quantum computing device. One type of quantum dot devices includes devices having a base, a fin extending away from the base, where the fin includes a quantum well layer, and one or more gates disposed on the fin. A quantum dot formed in such a device may be constrained in the x-direction by the one or more gates, in the y-direction by the fin, and in the z-direction by the quantum well layer, as discussed in detail herein. Unlike previous approaches to quantum dot formation and manipulation, quantum dot devices with fins provide strong spatial localization of the quantum dots (and therefore good control over quantum dot interactions and manipulation), good scalability in the number of quantum dots included in the device, and/or design flexibility in making electrical connections to the quantum dot devices to integrate the quantum dot devices in larger computing devices. Therefore, this is the type of a qubit device that is described as a first example qubit device that may be used in a quantum circuit assembly configured to implement active pulse shaping to control multiple qubits with a shared transmission channel, e.g., with a shared RF transmission line, as described herein, according to some embodiments of the present disclosure.

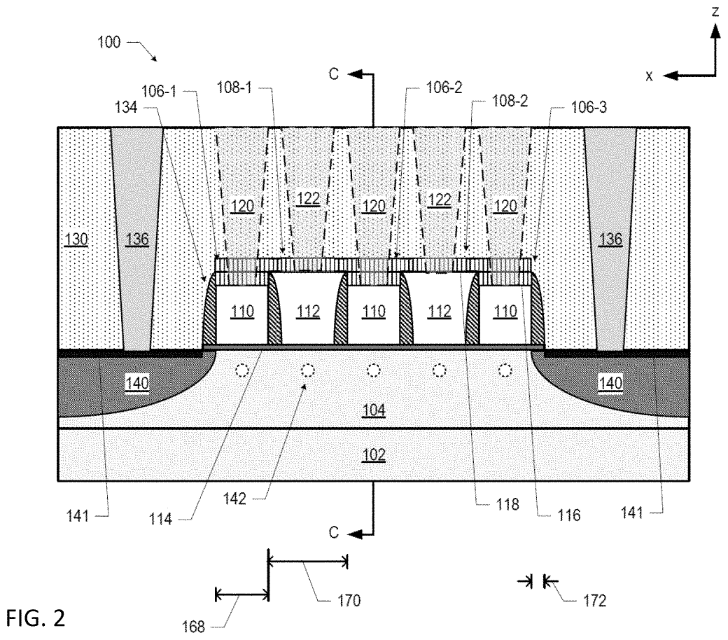

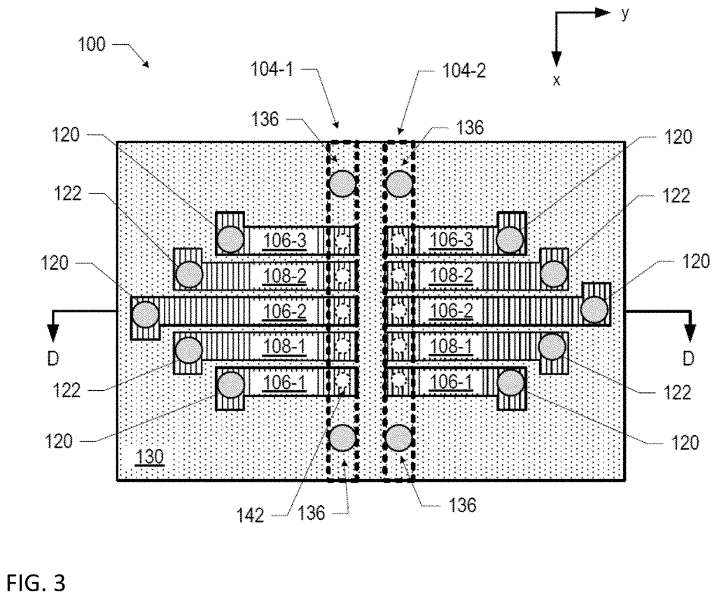

FIGS. 1-3 are cross-sectional views of an example quantum dot device 100 implementing quantum dot qubits, in accordance with various embodiments. In particular, FIG. 2 illustrates the quantum dot device 100 taken along the section A-A of FIG. 1 (while FIG. 1 illustrates the quantum dot device 100 taken along the section C-C of FIG. 2), and FIG. 3 illustrates the quantum dot device 100 taken along the section B-B of FIG. 1 (while FIG. 1 illustrates a quantum dot device 100 taken along the section D-D of FIG. 3). Although FIG. 1 indicates that the cross-section illustrated in FIG. 2 is taken through the fin 104-1, an analogous cross-section taken through the fin 104-2 may be identical, and thus the discussion of FIGS. 1-3 refers generally to the “fin 104.”

A quantum circuit component to be used in a quantum circuit assembly configured to implement active pulse shaping to control multiple qubits with a shared transmission channel as described herein may include one or more of the quantum dot devices 100.

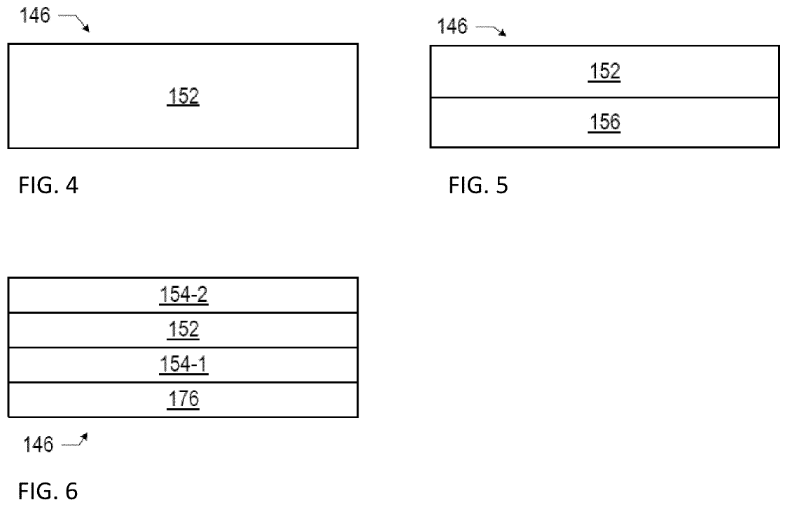

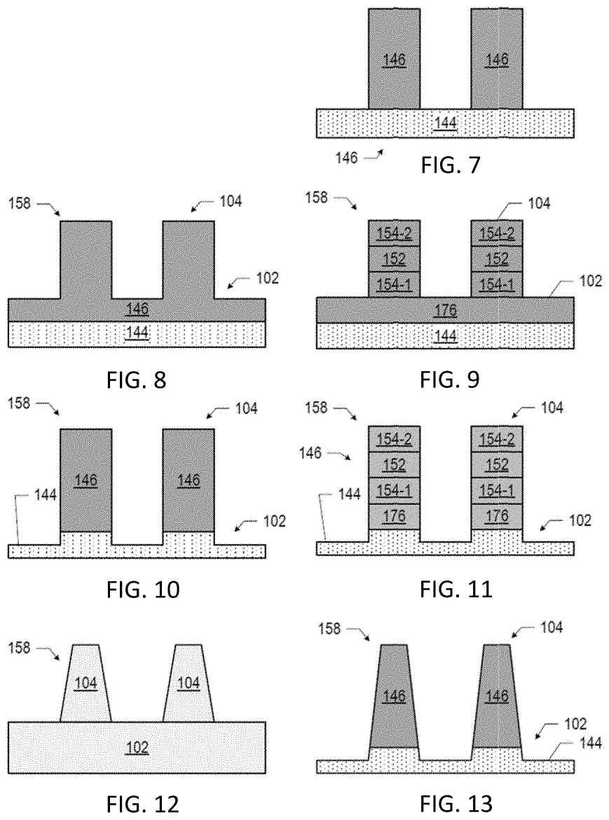

As shown in FIGS. 1-3, the quantum dot device 100 may include a base 102 and multiple fins 104 extending away from the base 102. The base 102 and the fins 104 may include a semiconductor substrate and a quantum well stack (not shown in FIGS. 1-3, but discussed below with reference to the semiconductor substrate 144 and the quantum well stack 146), distributed in any of a number of ways between the base 102 and the fins 104. The base 102 may include at least some of the semiconductor substrate, and the fins 104 may each include a quantum well layer of the quantum well stack (discussed below with reference to the quantum well layer 152 of FIGS. 4-6). Examples of base/fin arrangements are discussed below with reference to the base fin arrangements 158 of FIGS. 7-13.

Although only two fins, 104-1 and 104-2, are shown in FIGS. 1-3, this is simply for ease of illustration, and more than two fins 104 may be included in the quantum dot device 100. In some embodiments, the total number of fins 104 included in the quantum dot device 100 is an even number, with the fins 104 organized into pairs including one active fin 104 and one read fin 104, as discussed in detail below. When the quantum dot device 100 includes more than two fins 104, the fins 104 may be arranged in pairs in a line (e.g., 2N fins total may be arranged in a 1×2N line, or a 2×N line) or in pairs in a larger array (e.g., 2N fins total may be arranged as a 4×N/2 array, a 6×N/3 array, etc.). The discussion herein will largely focus on a single pair of fins 104 for ease of illustration, but all the teachings of the present disclosure apply to quantum dot devices 100 with more fins 104.

As noted above, each of the fins 104 may include a quantum well layer (not shown in FIGS. 1-3, but discussed below with reference to the quantum well layer 152). The quantum well layer included in the fins 104 may be arranged normal to the z-direction, and may provide a layer in which a two-dimensional electron gas (2DEG) may form to enable the generation of a quantum dot during operation of the quantum dot device 100, as discussed in further detail below. The quantum well layer itself may provide a geometric constraint on the z-location of quantum dots in the fins 104, and the limited extent of the fins 104 (and therefore the quantum well layer) in the y-direction may provide a geometric constraint on the y-location of quantum dots in the fins 104. To control the x-location of quantum dots in the fins 104, voltages may be applied to gates disposed on the fins 104 to adjust the energy profile along the fins 104 in the x-direction and thereby constrain the x-location of quantum dots within quantum wells (discussed in detail below with reference to the gates 106/108). The dimensions of the fins 104 may take any suitable values. For example, in some embodiments, the fins 104 may each have a width 162 between 10 and 30 nanometers. In some embodiments, the fins 104 may each have a height 164 between 200 and 400 nanometers (e.g., between 250 and 350 nanometers, or equal to 300 nanometers).

The fins 104 may be arranged in parallel, as illustrated in FIGS. 1 and 3, and may be spaced apart by an insulating material 128, which may be disposed on opposite faces of the fins 104. The insulating material 128 may be a dielectric material, such as silicon oxide. For example, in some embodiments, the fins 104 may be spaced apart by a distance 160 between 100 and 250 microns.

Multiple gates may be disposed on each of the fins 104. In the embodiment illustrated in FIG. 2, three gates 106 and two gates 108 are shown as distributed on the top of the fin 104. This particular number of gates is simply illustrative, and any suitable number of gates may be used. Additionally, multiple groups of gates like the gates illustrated in FIG. 2 may be disposed on the fin 104.

As shown in FIG. 2, the gate 108-1 may be disposed between the gates 106-1 and 106-2, and the gate 108-2 may be disposed between the gates 106-2 and 106-3. Each of the gates 106/108 may include a gate dielectric 114. In the embodiment illustrated in FIG. 2, the gate dielectric 114 for all of the gates 106/108 is provided by a common layer of gate dielectric material. In other embodiments, the gate dielectric 114 for each of the gates 106/108 may be provided by separate portions of gate dielectric 114. In some embodiments, the gate dielectric 114 may be a multilayer gate dielectric (e.g., with multiple materials used to improve the interface between the fin 104 and the corresponding gate metal). The gate dielectric 114 may be, for example, silicon oxide, aluminum oxide, or a high-k dielectric, such as hafnium oxide. More generally, the gate dielectric 114 may include elements such as hafnium, silicon, oxygen, titanium, tantalum, lanthanum, aluminum, zirconium, barium, strontium, yttrium, lead, scandium, niobium, and zinc. Examples of materials that may be used in the gate dielectric 114 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 114 to improve the quality of the gate dielectric 114.

Each of the gates 106 may include a gate metal 110 and a hardmask 116. The hardmask 116 may be formed of silicon nitride, silicon carbide, or another suitable material. The gate metal 110 may be disposed between the hardmask 116 and the gate dielectric 114, and the gate dielectric 114 may be disposed between the gate metal 110 and the fin 104. Only one portion of the hardmask 116 is labeled in FIG. 2 for ease of illustration. In some embodiments, the gate metal 110 may be a superconductor, such as aluminum, titanium nitride (e.g., deposited via atomic layer deposition), or niobium titanium nitride. In some embodiments, the hardmask 116 may not be present in the quantum dot device 100 (e.g., a hardmask like the hardmask 116 may be removed during processing, as discussed below). The sides of the gate metal 110 may be substantially parallel, as shown in FIG. 2, and insulating spacers 134 may be disposed on the sides of the gate metal 110 and the hardmask 116. As illustrated in FIG. 2, the spacers 134 may be thicker closer to the fin 104 and thinner farther away from the fin 104. In some embodiments, the spacers 134 may have a convex shape. The spacers 134 may be formed of any suitable material, such as a carbon-doped oxide, silicon nitride, silicon oxide, or other carbides or nitrides (e.g., silicon carbide, silicon nitride doped with carbon, and silicon oxynitride). The gate metal 110 may be any suitable metal, such as titanium nitride.

Each of the gates 108 may include a gate metal 112 and a hardmask 118. The hardmask 118 may be formed of silicon nitride, silicon carbide, or another suitable material. The gate metal 112 may be disposed between the hardmask 118 and the gate dielectric 114, and the gate dielectric 114 may be disposed between the gate metal 112 and the fin 104. In the embodiment illustrated in FIG. 2, the hardmask 118 may extend over the hardmask 116 (and over the gate metal 110 of the gates 106), while in other embodiments, the hardmask 118 may not extend over the gate metal 110 (e.g., as discussed below with reference to FIG. 45). In some embodiments, the gate metal 112 may be a different metal from the gate metal 110; in other embodiments, the gate metal 112 and the gate metal 110 may have the same material composition. In some embodiments, the gate metal 112 may be a superconductor, such as aluminum, titanium nitride (e.g., deposited via atomic layer deposition), or niobium titanium nitride. In some embodiments, the hardmask 118 may not be present in the quantum dot device 100 (e.g., a hardmask like the hardmask 118 may be removed during processing, as discussed below).

The gate 108 may extend between the proximate spacers 134 on the sides of the gate 106-1 and the gate 106-3, as shown in FIG. 2. In some embodiments, the gate metal 112 may extend between the spacers 134 on the sides of the gate 106-1 and the gate 106-3. Thus, the gate metal 112 may have a shape that is substantially complementary to the shape of the spacers 134, as shown. In some embodiments in which the gate dielectric 114 is not a layer shared commonly between the gates 108 and 106, but instead is separately deposited on the fin 104 between the spacers 134 (e.g., as discussed below with reference to FIGS. 40-44), the gate dielectric 114 may extend at least partially up the sides of the spacers 134, and the gate metal 112 may extend between the portions of gate dielectric 114 on the spacers 134. The gate metal 112, like the gate metal 110, may be any suitable metal, such as titanium nitride.

The dimensions of the gates 106/108 may take any suitable values. For example, in some embodiments, the z-height 166 of the gate metal 110 may be between 40 and 75 nanometers (e.g., approximately 50 nanometers); the z-height of the gate metal 112 may be in the same range. In embodiments like the ones illustrated in FIG. 2, the z-height of the gate metal 112 may be greater than the z-height of the gate metal 110. In some embodiments, the length 168 of the gate metal 110 (i.e., in the x-direction) may be between 20 and 40 nanometers (e.g., 30 nanometers). In some embodiments, the distance 170 between adjacent ones of the gates 106 (e.g., as measured from the gate metal 110 of one gate 106 to the gate metal 110 of an adjacent gate 106 in the x-direction, as illustrated in FIG. 2) may be between 40 and 60 nanometers (e.g., 50 nanometers). In some embodiments, the thickness 172 of the spacers 134 may be between 1 and 10 nanometers (e.g., between 3 and 5 nanometers, between 4 and 6 nanometers, or between 4 and 7 nanometers). The length of the gate metal 112 (i.e., in the x-direction) may depend on the dimensions of the gates 106 and the spacers 134, as illustrated in FIG. 2. As indicated in FIG. 1, the gates 106/108 on one fin 104 may extend over the insulating material 128 beyond their respective fins 104 and towards the other fin 104, but may be isolated from their counterpart gates by the intervening insulating material 130.

As shown in FIG. 2, the gates 106 and 108 may be alternatingly arranged along the fin 104 in the x-direction. During operation of the quantum dot device 100, voltages may be applied to the gates 106/108 to adjust the potential energy in the quantum well layer (not shown) in the fin 104 to create quantum wells of varying depths in which quantum dots 142 may form. Only one quantum dot 142 is labeled with a reference numeral in FIGS. 2 and 3 for ease of illustration, but five are indicated as dotted circles in each fin 104, forming what may be referred to as a “quantum dot array.” The location of the quantum dots 142 in FIG. 2 is not intended to indicate a particular geometric positioning of the quantum dots 142. The spacers 134 may themselves provide “passive” barriers between quantum wells under the gates 106/108 in the quantum well layer, and the voltages applied to different ones of the gates 106/108 may adjust the potential energy under the gates 106/108 in the quantum well layer; decreasing the potential energy may form quantum wells, while increasing the potential energy may form quantum barriers.

The fins 104 may include doped regions 140 that may serve as a reservoir of charge carriers for the quantum dot device 100. For example, an n-type doped region 140 may supply electrons for electron-type quantum dots 142, and a p-type doped region 140 may supply holes for hole-type quantum dots 142. In some embodiments, an interface material 141 may be disposed at a surface of a doped region 140, as shown. The interface material 141 may facilitate electrical coupling between a conductive contact (e.g., a conductive via 136, as discussed below) and the doped region 140. The interface material 141 may be any suitable material; for example, in embodiments in which the doped region 140 includes silicon, the interface material 141 may include nickel silicide.

The quantum dot devices 100 disclosed herein may be used to form electron-type or hole-type quantum dots 142. Note that the polarity of the voltages applied to the gates 106/108 to form quantum wells/barriers depend on the charge carriers used in the quantum dot device 100. In embodiments in which the charge carriers are electrons (and thus the quantum dots 142 are electron-type quantum dots), amply negative voltages applied to a gate 106/108 may increase the potential barrier under the gate 106/108, and amply positive voltages applied to a gate 106/108 may decrease the potential barrier under the gate 106/108 (thereby forming a potential well in which an electron-type quantum dot 142 may form). In embodiments in which the charge carriers are holes (and thus the quantum dots 142 are hole-type quantum dots), amply positive voltages applied to a gate 106/108 may increase the potential barrier under the gate 106/108, and amply negative voltages applied to a gate 106 and 108 may decrease the potential barrier under the gate 106/108 (thereby forming a potential well in which a hole-type quantum dot 142 may form). The quantum dot devices 100 disclosed herein may be used to form electron-type or hole-type quantum dots.

Voltages may be applied to each of the gates 106 and 108 separately to adjust the potential energy in the quantum well layer under the gates 106 and 108, and thereby control the formation of quantum dots 142 under each of the gates 106 and 108. Additionally, the relative potential energy profiles under different ones of the gates 106 and 108 allow the quantum dot device 100 to tune the potential interaction between quantum dots 142 under adjacent gates. For example, if two adjacent quantum dots 142 (e.g., one quantum dot 142 under a gate 106 and another quantum dot 142 under a gate 108) are separated by only a short potential barrier, the two quantum dots 142 may interact more strongly than if they were separated by a taller potential barrier. Since the depth of the potential wells/height of the potential barriers under each gate 106/108 may be adjusted by adjusting the voltages on the respective gates 106/108, the differences in potential between adjacent gates 106/108 may be adjusted, and thus the interaction tuned.

In some applications, the gates 108 may be used as plunger gates to enable the formation of quantum dots 142 under the gates 108, while the gates 106 may be used as barrier gates to adjust the potential barrier between quantum dots 142 formed under adjacent gates 108. In other applications, the gates 108 may be used as barrier gates, while the gates 106 are used as plunger gates. In other applications, quantum dots 142 may be formed under all of the gates 106 and 108, or under any desired subset of the gates 106 and 108.

Conductive vias and lines may make contact with the gates 106/108, and to the doped regions 140, to enable electrical connection to the gates 106/108 and the doped regions 140 to be made in desired locations. As shown in FIGS. 1-3, the gates 106 may extend away from the fins 104, and conductive vias 120 may contact the gates 106 (and are drawn in dashed lines in FIG. 2 to indicate their location behind the plane of the drawing). The conductive vias 120 may extend through the hardmask 116 and the hardmask 118 to contact the gate metal 110 of the gates 106. The gates 108 may extend away from the fins 104, and conductive vias 122 may contact the gates 108 (also drawn in dashed lines in FIG. 2 to indicate their location behind the plane of the drawing). The conductive vias 122 may extend through the hardmask 118 to contact the gate metal 112 of the gates 108. Conductive vias 136 may contact the interface material 141 and may thereby make electrical contact with the doped regions 140. The quantum dot device 100 may include further conductive vias and/or lines (not shown) to make electrical contact to the gates 106/108 and/or the doped regions 140, as desired.

During operation, a bias voltage may be applied to the doped regions 140 (e.g., via the conductive vias 136 and the interface material 141) to cause current to flow through the doped regions 140. When the doped regions 140 are doped with an n-type material, this voltage may be positive; when the doped regions 140 are doped with a p-type material, this voltage may be negative. The magnitude of this bias voltage may take any suitable value (e.g., between 0.25 volts and 2 volts).

The conductive vias 120, 122, and 136 may be electrically isolated from each other by an insulating material 130. The insulating material 130 may be any suitable material, such as an interlayer dielectric (ILD). Examples of the insulating material 130 may include silicon oxide, silicon nitride, aluminum oxide, and/or silicon oxynitride. As known in the art of IC manufacturing, conductive vias and lines may be formed in an iterative process in which layers of structures are formed on top of each other. In some embodiments, the conductive vias 120/122/136 may have a width that is 20 nanometers or greater at their widest point (e.g., 30 nanometers), and a pitch of 80 nanometers or greater (e.g., 100 nanometers). In some embodiments, conductive lines (not shown) included in the quantum dot device 100 may have a width that is 100 nanometers or greater, and a pitch of 100 nanometers or greater. The particular arrangement of conductive vias shown in FIGS. 1-3 is simply illustrative, and any electrical routing arrangement may be implemented.

As discussed above, the structure of the fin 104-1 may be the same as the structure of the fin 104-2; similarly, the construction of gates 106/108 on the fin 104-1 may be the same as the construction of gates 106/108 on the fin 104-2. The gates 106/108 on the fin 104-1 may be mirrored by corresponding gates 106/108 on the parallel fin 104-2, and the insulating material 130 may separate the gates 106/108 on the different fins 104-1 and 104-2. In particular, quantum dots 142 formed in the fin 104-1 (under the gates 106/108) may have counterpart quantum dots 142 in the fin 104-2 (under the corresponding gates 106/108). In some embodiments, the quantum dots 142 in the fin 104-1 may be used as “active” quantum dots in the sense that these quantum dots 142 act as qubits and are controlled (e.g., by voltages applied to the gates 106/108 of the fin 104-1) to perform quantum computations. The quantum dots 142 in the fin 104-2 may be used as “read” quantum dots in the sense that these quantum dots 142 may sense the quantum state of the quantum dots 142 in the fin 104-1 by detecting the electric field generated by the charge in the quantum dots 142 in the fin 104-1, and may convert the quantum state of the quantum dots 142 in the fin 104-1 into electrical signals that may be detected by the gates 106/108 on the fin 104-2. Each quantum dot 142 in the fin 104-1 may be read by its corresponding quantum dot 142 in the fin 104-2. Thus, the quantum dot device 100 enables both quantum computation and the ability to read the results of a quantum computation.

Although not specifically shown in FIGS. 1-3, the quantum dot device 100 may further include one or more accumulation gates used to form a 2DEG in the quantum well area between the area with the quantum dots and the reservoir such as e.g. the doped regions 140 which, as previously described, may serve as a reservoir of charge carriers for the quantum dot device 100. Using such accumulation gates may allow to reduce the number of charge carriers in the area adjacent to the area in which quantum dots are to be formed, so that single charge carriers can be transferred from the reservoir into the quantum dot array. In various embodiments, an accumulation gate may be implemented on either side of an area where a quantum dot is to be formed.

As discussed above, the base 102 and the fin 104 of a quantum dot device 100 may be formed from a semiconductor substrate 144 and a quantum well stack 146 disposed on the semiconductor substrate 144. The quantum well stack 146 may include a quantum well layer in which a 2DEG may form during operation of the quantum dot device 100. The quantum well stack 146 may take any of a number of forms, several of which are illustrated in FIGS. 4-6. The various layers in the quantum well stacks 146 discussed below may be grown on the semiconductor substrate 144 (e.g., using epitaxial processes).

FIG. 4 is a cross-sectional view of a quantum well stack 146 including only a quantum well layer 152. The quantum well layer 152 may be disposed on the semiconductor substrate 144, and may be formed of a material such that, during operation of the quantum dot device 100, a 2DEG may form in the quantum well layer 152 proximate to the upper surface of the quantum well layer 152. The gate dielectric 114 of the gates 106/108 may be disposed on the upper surface of the quantum well layer 152. In some embodiments, the quantum well layer 152 of FIG. 4 may be formed of intrinsic silicon, and the gate dielectric 114 may be formed of silicon oxide; in such an arrangement, during use of the quantum dot device 100, a 2DEG may form in the intrinsic silicon at the interface between the intrinsic silicon and the silicon oxide. In some such embodiments, the intrinsic silicon may be strained, while in other embodiments, the intrinsic silicon may not be strained. The thicknesses (i.e., z-heights) of the layers in the quantum well stack 146 of FIG. 4 may take any suitable values. For example, in some embodiments, the thickness of the quantum well layer 152 (e.g., intrinsic silicon) may be between 0.8 and 1.2 microns.

FIG. 5 is a cross-sectional view of a quantum well stack 146 including a quantum well layer 152 and a barrier layer 154. The quantum well stack 146 may be disposed on a semiconductor substrate 144 such that the barrier layer 154 is disposed between the quantum well layer 152 and the semiconductor substrate 144. The barrier layer 154 may provide a potential barrier between the quantum well layer 152 and the semiconductor substrate 144. As discussed above with reference to FIG. 4, the quantum well layer 152 of FIG. 5 may be formed of a material such that, during operation of the quantum dot device 100, a 2DEG may form in the quantum well layer 152 proximate to the upper surface of the quantum well layer 152. For example, in some embodiments in which the semiconductor substrate 144 is formed of silicon, the quantum well layer 152 of FIG. 5 may be formed of silicon, and the barrier layer 154 may be formed of silicon germanium. The germanium content of this silicon germanium may be 20-80% (e.g., 30%). The thicknesses (i.e., z-heights) of the layers in the quantum well stack 146 of FIG. 5 may take any suitable values. For example, in some embodiments, the thickness of the barrier layer 154 (e.g., silicon germanium) may be between 0 and 400 nanometers. In some embodiments, the thickness of the quantum well layer 152 (e.g., silicon) may be between 5 and 30 nanometers.

FIG. 6 is a cross-sectional view of a quantum well stack 146 including a quantum well layer 152 and a barrier layer 154-1, as well as a buffer layer 176 and an additional barrier layer 154-2. The quantum well stack 146 may be disposed on the semiconductor substrate 144 such that the buffer layer 176 is disposed between the barrier layer 154-1 and the semiconductor substrate 144. The buffer layer 176 may be formed of the same material as the barrier layer 154, and may be present to trap defects that form in this material as it is grown on the semiconductor substrate 144. In some embodiments, the buffer layer 176 may be grown under different conditions (e.g., deposition temperature or growth rate) from the barrier layer 154-1. In particular, the barrier layer 154-1 may be grown under conditions that achieve fewer defects than the buffer layer 176. In some embodiments in which the buffer layer 176 includes silicon germanium, the silicon germanium of the buffer layer 176 may have a germanium content that varies from the semiconductor substrate 144 to the barrier layer 154-1. For example, the silicon germanium of the buffer layer 176 may have a germanium content that varies from zero percent at the silicon semiconductor substrate 144 to a nonzero percent (e.g., 30%) at the barrier layer 154-1. The thicknesses (i.e., z-heights) of the layers in the quantum well stack 146 of FIG. 6 may take any suitable values. For example, in some embodiments, the thickness of the buffer layer 176 (e.g., silicon germanium) may be between 0.3 and 4 microns (e.g., 0.3-2 microns, or 0.5 microns). In some embodiments, the thickness of the barrier layer 154-1 (e.g., silicon germanium) may be between 0 and 400 nanometers. In some embodiments, the thickness of the quantum well layer 152 (e.g., silicon) may be between 5 and 30 nanometers (e.g., 10 nanometers). In some embodiments, the thickness of the barrier layer 154-2 (e.g., silicon germanium) may be between 25 and 75 nanometers (e.g., 32 nanometers).

As discussed above with reference to FIG. 5, the quantum well layer 152 of FIG. 6 may be formed of a material such that, during operation of the quantum dot device 100, a 2DEG may form in the quantum well layer 152 proximate to the upper surface of the quantum well layer 152. For example, in some embodiments in which the semiconductor substrate 144 is formed of silicon, the quantum well layer 152 of FIG. 6 may be formed of silicon, and the barrier layer 154-1 and the buffer layer 176 may be formed of silicon germanium. In some such embodiments, the silicon germanium of the buffer layer 176 may have a germanium content that varies from the semiconductor substrate 144 to the barrier layer 154-1. For example, the silicon germanium of the buffer layer 176 may have a germanium content that varies from zero percent at the silicon semiconductor substrate 144 to a nonzero percent (e.g., 30%) at the barrier layer 154-1. The barrier layer 154-1 may in turn have a germanium content equal to the nonzero percent. In other embodiments, the buffer layer 176 may have a germanium content equal to the germanium content of the barrier layer 154-1, but may be thicker than the barrier layer 154-1 so as to absorb the defects that may arise during growth. The barrier layer 154-2, like the barrier layer 154-1, may provide a potential energy barrier around the quantum well layer 152, and may take the form of any of the embodiments of the barrier layer 154-1. In some embodiments of the quantum well stack 146 of FIG. 6, the buffer layer 176 and/or the barrier layer 154-2 may be omitted.

The semiconductor substrate 144 and the quantum well stack 146 may be distributed between the base 102 and the fins 104 of the quantum dot device 100, as discussed above. This distribution may occur in any of a number of ways. For example, FIGS. 7-13 illustrate example base/fin arrangements 158 that may be used in a quantum dot device 100, in accordance with various embodiments.

In the base/fin arrangement 158 of FIG. 7, the quantum well stack 146 may be included in the fins 104, but not in the base 102. The semiconductor substrate 144 may be included in the base 102, but not in the fins 104. Manufacturing of the base/fin arrangement 158 of FIG. 7 may include fin etching through the quantum well stack 146, stopping when the semiconductor substrate 144 is reached.

In the base/fin arrangement 158 of FIG. 8, the quantum well stack 146 may be included in the fins 104, as well as in a portion of the base 102. A semiconductor substrate 144 may be included in the base 102 as well, but not in the fins 104. Manufacturing of the base/fin arrangement 158 of FIG. 8 may include fin etching that etches partially through the quantum well stack 146, and stops before the semiconductor substrate 144 is reached. FIG. 9 illustrates a particular embodiment of the base/fin arrangement 158 of FIG. 8. In the embodiment of FIG. 9, the quantum well stack 146 of FIG. 6 is used; the fins 104 include the barrier layer 154-1, the quantum well layer 152, and the barrier layer 154-2, while the base 102 includes the buffer layer 176 and the semiconductor substrate 144.

In the base/fin arrangement 158 of FIG. 10, the quantum well stack 146 may be included in the fins 104, but not the base 102. The semiconductor substrate 144 may be partially included in the fins 104, as well as in the base 102. Manufacturing the base/fin arrangement 158 of FIG. 10 may include fin etching that etches through the quantum well stack 146 and into the semiconductor substrate 144 before stopping. FIG. 11 illustrates a particular embodiment of the base/fin arrangement 158 of FIG. 10. In the embodiment of FIG. 11, the quantum well stack 146 of FIG. 6 is used; the fins 104 include the quantum well stack 146 and a portion of the semiconductor substrate 144, while the base 102 includes the remainder of the semiconductor substrate 144.

Although the fins 104 have been illustrated in many of the preceding figures as substantially rectangular with parallel sidewalls, this is simply for ease of illustration, and the fins 104 may have any suitable shape (e.g., shape appropriate to the manufacturing processes used to form the fins 104). For example, as illustrated in the base/fin arrangement 158 of FIG. 12, in some embodiments, the fins 104 may be tapered. In some embodiments, the fins 104 may taper by 3-10 nanometers in x-width for every 100 nanometers in z-height (e.g., 5 nanometers in x-width for every 100 nanometers in z-height). When the fins 104 are tapered, the wider end of the fins 104 may be the end closest to the base 102, as illustrated in FIG. 12. FIG. 13 illustrates a particular embodiment of the base/fin arrangement 158 of FIG. 12. In FIG. 13, the quantum well stack 146 is included in the tapered fins 104 while a portion of the semiconductor substrate 144 is included in the tapered fins and a portion of the semiconductor substrate 144 provides the base 102.

In the embodiment of the quantum dot device 100 illustrated in FIG. 2, the z-height of the gate metal 112 of the gates 108 may be approximately equal to the sum of the z-height of the gate metal 110 and the z-height of the hardmask 116, as shown. Also in the embodiment of FIG. 2, the gate metal 112 of the gates 108 may not extend in the x-direction beyond the adjacent spacers 134. In other embodiments, the z-height of the gate metal 112 of the gates 108 may be greater than the sum of the z-height of the gate metal 110 and the z-height of the hardmask 116, and in some such embodiments, the gate metal 112 of the gates may extend beyond the spacers 134 in the x-direction.

Example Quantum Circuit Components with Superconducting Qubits

Superconducting qubits are also promising candidates for building a quantum computer. Therefore, these are the types of qubit devices that may be used in a second example qubit device that may be used in a quantum circuit assembly configured to implement active pulse shaping to control multiple qubits with a shared transmission channel, e.g., with a shared RF transmission line, as described herein, according to some embodiments of the present disclosure.

As shown in FIG. 14, an example superconducting quantum circuit 200 may include two or more qubits 202 (reference numerals following a dash, such as e.g. qubit 202-1 and 202-2 indicate different instances of the same or analogous element). All of superconducting qubits operate based on the Josephson effect, which refers to a macroscopic quantum phenomenon of supercurrent, i.e. a current that, due to zero electrical resistance, flows indefinitely long without any voltage applied, across a non-linear inductive element such as, e.g., a Josephson Junction. Non-linear inductive elements such as Josephson Junctions are integral building blocks in superconducting quantum circuits where they form the basis of quantum circuit elements that can approximate functionality of theoretically designed qubits. Therefore, each of the superconducting qubits 202 may include one or more Josephson Junctions 204, as illustrated in FIG. 14.

In general, a Josephson Junction includes two superconductors coupled by a so-called weak link that weakens the superconductivity between the two superconductors. In some embodiments, weak links of Josephson Junctions may be implemented by providing a thin layer of an insulating material, a conductive but not superconductive material, or a semiconducting material, typically referred to as a “barrier” or a “tunnel barrier,” sandwiched, in a stack-like arrangement, between two layers of superconductor, which two superconductors typically referred to, respectively, as a “first electrode” and a “second electrode” of a Josephson Junction. Josephson Junction provides a non-linear inductive element to the circuit and allows the qubit to become an anharmonic oscillator. The anharmonicity is what allows the state of the qubit to be controlled to a high level of fidelity.

Typically, when a qubit employs only one Josephson Junction, a frequency of the qubit cannot be changed substantially beyond what is defined by the design unless one of the qubit capacitive elements is tunable. Employing two or more Josephson Junctions, e.g. arranged in a so-called superconducting quantum interference device (SQUID), allows controlling the frequency of the qubit, which, in turn, allows greater control as to whether and when the qubit interacts with other components of a quantum circuit, e.g. with other qubits. In general, a SQUID of a superconducting qubit includes a pair of Josephson Junctions and a loop of a conductive, typically superconductive material (i.e. a superconducting loop), connecting a pair of Josephson Junctions. Applying a net magnetic field in a certain orientation to the SQUID loop of a superconducting qubit allows controlling the frequency of the qubit. In particular, applying magnetic field to the SQUID region of a superconducting qubit is generally referred to as a “flux control” of a qubit, and the magnetic field is generated by providing DC or a pulse of current through an electrically conductive or superconductive line generally referred to as a “flux bias line” (also known as a “flux line” or a “flux coil line”). By providing flux bias lines sufficiently close to SQUIDs, magnetic fields generated as a result of currents running through the flux bias lines extend to the SQUIDs, thus tuning qubit frequencies.

Turning back to FIG. 14, within each qubit 202, the one or more Josephson Junctions 204 may be directly electrically connected to one or more other circuit elements 206, which, in combination with the Josephson Junction(s) 204, form a non-linear oscillator circuit providing multi-level quantum system where the first two to three levels define the qubit under normal operation. The circuit elements 206 could be e.g. shunt capacitors, superconducting loops of a SQUID, electrodes for setting an overall capacitance of a qubit, or/and ports for capacitively coupling the qubit to one or more of a readout resonator, a coupling or “bus” component, and a direct microwave drive line, or electromagnetically coupling the qubit to a flux bias line.

As also shown in FIG. 14, an example superconducting quantum circuit 200 may include means 208 for providing external control of qubits 202 and means 210 for providing internal control of qubits 202. In this context, “external control” refers to controlling the qubits 202 from outside of, e.g. an IC chip comprising the qubits, including control by a user of a quantum computer, while “internal control” refers to controlling the qubits 202 within the IC chip. For example, if qubits 202 are transmons, external control may be implemented by means of flux bias lines (also known as “flux lines” and “flux coil lines”) and by means of readout and drive lines (also known as “microwave lines” since qubits are typically designed to operate with microwave signals), described in greater detail below. On the other hand, internal control lines for such qubits may be implemented by means of resonators, e.g., coupling and readout resonators, also described in greater detail below.

Any one of the qubits 202, the external control means 208, and the external control means 210 of the quantum circuit 200 may be provided on, over, or at least partially embedded in a substrate (not shown in FIG. 14).

FIG. 15 provides a schematic illustration of an example physical layout of a superconducting quantum circuit 211 where qubits are implemented as transmons, according to some embodiments of the present disclosure.

Similar to FIG. 14, FIG. 15 illustrates two qubits 202. In addition, FIG. 15 illustrates flux bias lines 212, microwave lines 214, a coupling resonator 216, a readout resonator 218, and connections (e.g. wirebonding pads or any other suitable connections) 220 and 222. The flux bias lines 212 and the microwave lines 214 may be viewed as examples of the external control means 208 shown in FIG. 14. The coupling resonator 216 and the readout resonator 218 may be viewed as examples of the internal control means 210 shown in FIG. 14.

Running a current through the flux bias lines 212, provided from the connections 220, allows tuning (i.e. changing) the frequency of the corresponding qubits 202 to which each line 212 is connected. In general, it operates in the following manner. As a result of running the current in a particular flux bias line 212, magnetic field is created around the line. If such a magnetic field is in sufficient proximity to the qubit 202, e.g. by a portion of the flux bias line 212 being provided next to the qubit 202, the magnetic field couples to the qubit, thereby changing the spacing between the energy levels of the qubit. This, in turn, changes the frequency of the qubit since the frequency is directly related to the spacing between the energy levels via Planck's equation. The Planck's equation is E=hv, where E is the energy (in this case the energy difference between energy levels of a qubit), h is the Planck's constant and v is the frequency (in this case the frequency of the qubit). As this equation illustrates, if E changes, then v changes. Provided there is sufficient multiplexing, different currents can be sent down each of the flux lines allowing for independent tuning of the various qubits.

Typically, the qubit frequency may be controlled in order to bring the frequency either closer to or further away from another resonant item, for example a coupling resonator such as 216 shown in FIG. 15 that connects two or more qubits together, as may be desired in a particular setting.

For example, if it is desirable that a first qubit 202 (e.g. the qubit 202 shown on the left side of FIG. 15) and a second qubit 202 (e.g. the qubit 202 shown on the right side of FIG. 15) interact, via the coupling resonator 216 connecting these qubits, then both qubits 202 may need to be tuned to be at nearly the same frequency. One way in which such two qubits could interact is that, if the frequency of the first qubit 202 is tuned very close to the resonant frequency of the coupling resonator 216, the first qubit can, when in the excited state, relax back down to the ground state by emitting a photon (similar to how an excited atom would relax) that would resonate within the coupling resonator 216. If the second qubit 202 is also at this energy (i.e. if the frequency of the second qubit is also tuned very close to the resonant frequency of the coupling resonator 216), then it can absorb the photon emitted from the first qubit, via the coupling resonator 216, and be excited from its ground state to an excited state. Thus, the two qubits interact in that a state of one qubit is controlled by the state of another qubit. In other scenarios, two qubits could interact via a coupling resonator at specific frequencies, but these three elements do not have to be tuned to be at nearly the same frequency with one another. In general, two or more qubits could be configured to interact with one another by tuning their frequencies to specific values or ranges.

On the other hand, it may sometimes be desirable that two qubits coupled by a coupling resonator do not interact, i.e. the qubits are independent. In this case, by applying magnetic flux, by means of controlling the current in the appropriate flux bias line, to one qubit it is possible to cause the frequency of the qubit to change enough so that the photon it could emit no longer has the right frequency to resonate on the coupling resonator. If there is nowhere for such a frequency-detuned photon to go, the qubit will be better isolated from its surroundings and will live longer in its current state. Thus, in general, two or more qubits could be configured to avoid or eliminate interactions with one another by tuning their frequencies to specific values or ranges.

The state(s) of each qubit 202 may be read by way of its corresponding readout resonator 218. As explained below, the qubit 202 induces a resonant frequency in the readout resonator 218. This resonant frequency is then passed to the microwave lines 214 and communicated to the pads 222.

To that end, a readout resonator 218 may be provided for each qubit. The readout resonator 218 may be a transmission line that includes a capacitive connection to ground on one side and is either shorted to the ground on the other side (for a quarter wavelength resonator) or has a capacitive connection to ground (for a half wavelength resonator), which results in oscillations within the transmission line (resonance), with the resonant frequency of the oscillations being close to the frequency of the qubit. The readout resonator 218 is coupled to the qubit by being in sufficient proximity to the qubit 202, more specifically in sufficient proximity to the capacitor of the qubit 202, when the qubit is implemented as a transmon, either through capacitive or inductive coupling. Due to a coupling between the readout resonator 218 and the qubit 202, changes in the state of the qubit 202 result in changes of the resonant frequency of the readout resonator 218. In turn, because the readout resonator 218 is in sufficient proximity to the microwave line 214, changes in the resonant frequency of the readout resonator 218 induce changes in the current in the microwave line 214, and that current can be read externally via the wire bonding pads 222.

The coupling resonator 216 allows coupling different qubits together, e.g. as described above, in order to realize quantum logic gates. The coupling resonator 216 is similar to the readout resonator 218 in that it is a transmission line that includes capacitive connections to ground on both sides (i.e. a half wavelength resonator), which also results in oscillations within the coupling resonator 216. Each side of the coupling resonator 216 is coupled (again, either capacitively or inductively) to a respective qubit by being in sufficient proximity to the qubit, namely in sufficient proximity to the capacitor of the qubit, when the qubit is implemented as a transmon. Because each side of the coupling resonator 216 has coupling with a respective different qubit, the two qubits are coupled together through the coupling resonator 216. In this manner, state of one qubit depends on the state of the other qubit, and the other way around. Thus, coupling resonators may be employed in order to use a state of one qubit to control a state of another qubit.

In some implementations, the microwave line 214 may be used to not only readout the state of the qubits as described above, but also to control the state of the qubits. When a single microwave line is used for this purpose, the line operates in a half-duplex mode where, at some times, it is configured to readout the state of the qubits, and, at other times, it is configured to control the state of the qubits. In other implementations, microwave lines such as the line 214 shown in FIG. 15 may be used to only readout the state of the qubits as described above, while separate drive lines such as e.g. drive lines 224 shown in FIG. 15, may be used to control the state of the qubits. In such implementations, the microwave lines used for readout may be referred to as readout lines (e.g. readout line 214), while microwave lines used for controlling the state of the qubits may be referred to as drive lines (e.g. drive lines 224). The drive lines 224 may control the state of their respective qubits 202 by providing, using e.g. connections 226 as shown in FIG. 15, a microwave pulse at the qubit frequency, which in turn stimulates (i.e. triggers) a transition between the states of the qubit. By varying the length of this pulse, a partial transition can be stimulated, giving a superposition of the states of the qubit.

Coupling resonators and readout resonators of the superconducting quantum circuit 200 or 211 may be configured for capacitive coupling to other circuit elements at one or both ends in order to have resonant oscillations, whereas flux bias lines and microwave lines are intended to be non-resonant microwave transmission lines. In general, a resonator of a quantum circuit differs from a non-resonant microwave transmission line in that a resonator is a transmission line that is deliberately designed to support resonant oscillations (i.e. resonance) within the line, under certain conditions. In contrast, non-resonant transmission lines may be similar to conventional microwave transmission lines in that they are designed to avoid resonances, especially resonances at frequencies/wavelengths close to the resonant frequencies/wavelengths of any resonators in the proximity of such non-resonant lines. Once non-resonant transmission lines are manufactured, some of them may inadvertently support some resonances, but, during its design, efforts are taken to minimize resonances, standing waves, and reflected signals as much as possible, so that all of the signals can be transmitted through these lines without, or with as little resonance as possible. For example, the ends of non-resonant transmission lines are typically engineered to have a specific impedance (e.g. substantially 50 Ohm) to minimize impedance mismatches to other circuit elements to which the lines are connected, in order to minimize the amount of reflected signal at transitions (e.g., transitions from the chip to the package, the package to the connector, etc.).

Each one of the resonators and non-resonant transmission lines of a superconducting quantum circuit may be implemented as any suitable architecture of a microwave transmission line, such as e.g. a coplanar waveguide, a stripline, a microstrip line, or an inverted microstrip line. Typical materials to make the lines and resonators include Al, Nb, NbN, TiN, MoRe, and NbTiN, all of which are particular types of superconductors. However, in various embodiments, other suitable superconductors and alloys of superconductors may be used as well.

In various embodiments, various lines and qubits shown in FIG. 15 could have shapes and layouts different from those shown in that FIG. For example, some lines or resonators may comprise more curves and turns while other lines or resonators may comprise less curves and turns, and some lines or resonators may comprise substantially straight lines. In some embodiments, various lines or resonators may intersect one another, in such a manner that they don't make an electrical connection, which can be done by using e.g. a bridge, bridging one interconnect over the other. As long as these lines and resonators operate in accordance with use of such lines and resonators as known in the art for which some example principles were described above, quantum circuits with different shapes and layouts of the lines, resonators and qubits than those illustrated in FIG. 15 are all within the scope of the present disclosure.

While FIGS. 14 and 15 illustrate examples of quantum circuits comprising only two qubits 202, embodiments with any larger number of qubits are possible and are within the scope of the present disclosure. Furthermore, while FIGS. 14 and 15 illustrate embodiments specific to transmons, subject matter disclosed herein is not limited in this regard and may include other embodiments of quantum circuits implementing other types of superconducting qubits that would also utilize Josephson Junctions or other non-linear inductive elements as described herein, all of which are within the scope of the present disclosure.

A quantum circuit component to be used in a quantum circuit assembly configured to implement active pulse shaping to control multiple qubits with a shared transmission channel as described herein may include one or more of the superconducting qubit devices 202.

### Implementing Active Pulse Shaping for Signals Provided to Quantum Circuit Components

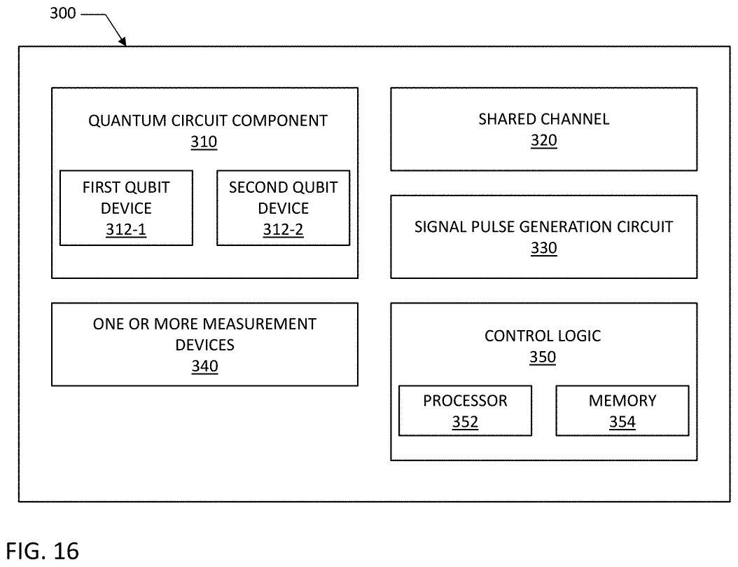

FIG. 16 provides a schematic illustration of a quantum circuit assembly 300 configured to implement active pulse shaping to control multiple qubits 312 of a quantum circuit component 310 with a shared transmission channel 320, according to some embodiments of the present disclosure.

The quantum circuit component 310 may be any component that can enable formation of one or more, typically a plurality, of qubits which may be used to perform quantum processing operations. For example, the quantum circuit component 310 may include one or more of the quantum dot qubits or superconducting qubits as described above. However, in general, the quantum circuit component 310 may include any type of qubits, all of which are within the scope of the present disclosure.

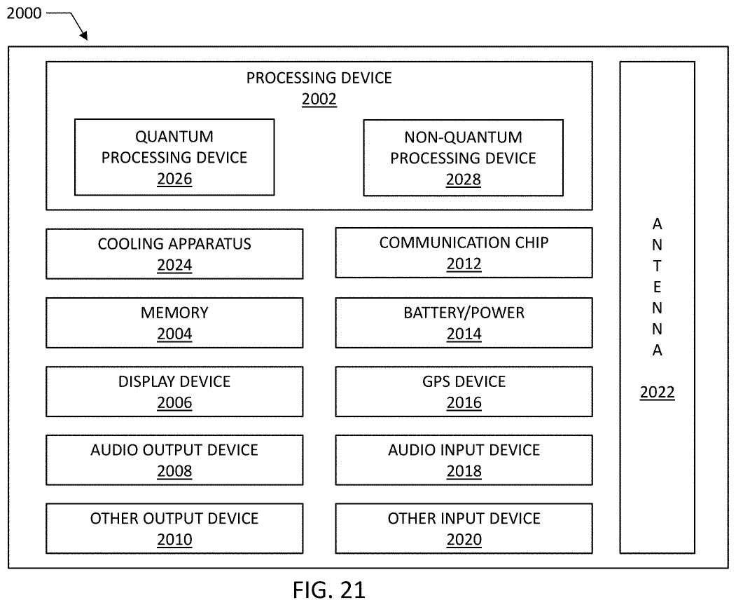

The individual qubit devices are illustrated in FIG. 16 as a first qubit device 312-1 and a second qubit device 312-2, although in further embodiments the quantum circuit component 310 may include any other number of qubit devices 312. In general, the term “die” refers to a small block of semiconductor material/substrate on which a particular functional circuit is fabricated. On the other hand, an IC chip, also referred to as simply a chip or a microchip, sometimes refers to a semiconductor wafer on which thousands or millions of such devices or dies are fabricated. However, other times, an IC chip refers to a portion of a semiconductor wafer (e.g. after the wafer has been diced) containing one or more dies, or the terms “chip” and “die” are used interchangeably. The quantum circuit component 310 may be any component that includes a plurality of qubits 312 which may be used to perform quantum processing operations. For example, the qubits 312 of the quantum circuit component 310 may include one or more quantum dot devices 100 or one or more devices 200 or 211 implementing superconducting qubits. However, in general, the quantum circuit component 310 may include any type of qubits 312, all of which are within the scope of the present disclosure. The quantum circuit component 310 may be a part of a quantum processing device, e.g. a part of a quantum processing device 2026 described with reference to FIG. 21.

Operation of the quantum circuit component 310 may begin with initialization of the qubits 312, which refers to a process of setting desired states for one or more of the qubits 312. However, the process of setting the desired states for one or more of the qubits 312 may also be carried out at later points in time during the operation of the quantum circuit component 310. In one example, in context of quantum dot qubits (i.e., when the qubits 312 are quantum dot qubits as described above), setting desired states for the one or more of the qubits 312 includes applying one or more signals to various gates 106 and/or 108 of the qubits 312 to set different quantum dot qubits to desired quantum states. In context of quantum dot qubits, a “state” of a qubit may refer to a spin state, e.g., one of two allowed values of a spin component (e.g. a spin up state or a spin down state) or any superposition of these values. In another example, in context of superconducting qubits (i.e., when the qubits 312 are superconducting qubits as described above), setting desired states for the one or more of the qubits 312 includes applying signal pulses to one or more drive lines 224 associated with the qubits 312 to set different superconducting qubits to desired quantum states. In context of superconducting qubits, a “state” of a qubit may refer to energy levels of a superconducting quantum anharmonic oscillator (e.g., ground state as state 0 and first excited state as state 1).

In some implementations of the quantum circuit assembly 300, a single, shared transmission channel 320, coupled to multiple ones of the qubits 312 (e.g., coupled to each of the qubit 312-1 and the qubit 312-2) may be used for providing signals to control states of multiple qubits 312. The shared transmission channel 320 may be implemented as any propagation channel that may be coupled to multiple qubits 312 and is suitable for supporting transmission of signal pulses configured to control qubit state(s) to various qubits 312. In some embodiments, the shared transmission channel 320 may be free space (i.e., a channel configured to support free space signal propagation). In various embodiments, the signal pulses propagating in free space may be either RF (e.g., microwave) or optical signal pulses. In other embodiments, the shared transmission channel 320 may be an optical transmission line. In other embodiments, the shared transmission channel 320 may be an RF transmission line (e.g., an RF/microwave transmission line) of any suitable transmission line architecture, such as e.g. a coplanar waveguide, a stripline, a microstrip line, or an inverted microstrip line. For example, in some embodiments, the shared transmission channel 320 may be implemented as an RF transmission line that is coupled to gates 106/108 of multiple quantum dot qubits when the qubits 312 are quantum dot qubits as described above, or the shared transmission channel 320 may be implemented as a drive line 224 (which may be another example of a shared RF transmission line) coupled to multiple superconducting qubits when the qubits 312 are superconducting qubits as described above. In some embodiments, the shared transmission channel 320 implemented as an RF transmission line may include or be made from any of the superconductive materials as described herein. The shared transmission channel 320 may be configured to control a state of a given qubit 312 by providing one or more signals pulses, e.g., RF signal pulses, at the respective qubit frequency associated with that qubit 312, which, in turn, stimulate (i.e., trigger) a transition between the states of the qubit 312. By varying the power and/or the length of this pulse, a partial transition can be stimulated, giving a superposition of the states of the qubit 312.

One challenge with conventional operation of signal channels coupled to multiple qubits is that, due to the sharing of the channel among multiple qubits, application of signals which are expected to lead to the desired qubit state for one qubit (e.g., the first qubit 312-1) may result in a change of the qubit state of another qubit (e.g., the second qubit 312-2). Such crosstalk may cause errors and uncertainties further down the line of processes carried out to operate the qubits and may even compromise the entire operation.

To reduce or eliminate the crosstalk due to sharing of the channel 320, the quantum circuit assembly 300 may further include a signal pulse generation circuit 330, as well as, optionally, one or more measurement devices 340, and a control logic 350. Although the signal pulse generation circuit 330, the one or more measurement devices 340, and the control logic 350 are shown in FIG. 16 as separate components, in general, functionality attributed to one component of the quantum circuit assembly 300 may be accomplished by a different component included in the quantum circuit assembly 300 or by a different system than what is illustrated in FIG. 16. For example, at least some of the functionality of the control logic 350 may be a part of the signal pulse generation circuit 330, and vice versa. Furthermore, even though the signal pulse generation circuit 330, the one or more measurement devices 340, and the control logic 350 are shown in FIG. 16 as being a part of the quantum circuit assembly 300, in other embodiments, one or more of the signal pulse generation circuit 330, the one or more measurement devices 340, and the control logic 350 may be implemented separate from but communicatively coupled to the quantum circuit assembly 300 to enable operation of the quantum circuit assembly 300 as described herein. In alternative configurations, different and/or additional components than what is shown in FIG. 16 may be included in the quantum circuit assembly 300.

The signal pulse generation circuit 330 may include any suitable electrical circuit configured to generate actively shaped signal pulses with one or more notches therein in accordance with various embodiments of the present disclosure. To that end, the signal pulse generation circuit 330 may include any number of suitable digital circuits such as digital filters, digital signal processing (DSP) units, arithmetic-logic units (ALU), counters, memory banks, etc., and/or analog circuits such as amplifiers, power amplifiers, current/voltage reference generators, impedance matching networks, clock generators, analog filters, mixers, digital to analog converters (DAC), etc. The signal pulse generation circuit 330 may be configured to provide the signal pulses to the shared transmission channel 320 so that the signal pulses may be propagated over the shared transmission channel 320 to control the states of one or more of the qubits 312.

The one or more measurement devices 340 may be included if it is desirable to adaptively adjust one or more parameters of the signal pulses generated by the signal pulse generation circuit 330 based on the measurements carried out by the one or more measurement devices 340. In various embodiments, the one or more measurement devices 340 may include any suitable devices for measuring measurable parameters (e.g. current, voltage, magnetic field, etc.) indicative of a state of any of the qubits 312 included in the quantum circuit components 310. Example of such measurement devices 340 may include, but are not limited to, a resonator circuit for RF reflectometry (which resonator circuit may be provided off-chip, i.e. on a different substrate or in a different IC package than the quantum circuit component 310), lock-in amplifier, and various suitable filters and amplifiers configured to perform measurements of parameters which are indicative of a state of the one or more qubits 312.

The control logic 350 may be configured to control various aspects of implementing active pulse shaping as described herein. For example, in some embodiments, the control logic 350 may be configured to generate parameters of the signal pulses to be generated by the signal pulse generation circuit 330. In some embodiments, the control logic 350 may be configured to perform adaptive programming of the signal pulses to be generated by the signal pulse generation circuit 330 based on the measurements carried out by the one or more measurement devices 340. To that end, two or more of the signal pulse generation circuit 330, the one or more measurement devices 340, and the control logic 350 may be communicatively connected with one another using suitable interconnects for communicating signals and data.

In some embodiments, at least portions, or all, of the control logic 350 may be advantageously integrated on the same die with at least portions, or all, of the quantum circuit component 310 and/or the signal pulse generation circuit 330. In other embodiments, the control logic 350 may be provided on a different die. In some embodiments, at least portions, or all, of the one or more measurement devices 340 may be advantageously integrated on the same die with at least portions, or all, of the quantum circuit component 310. In other embodiments, the one or more measurement devices 340 may be provided on a different die. In general, a device is referred to as “integrated” if it is manufactured on one or more dies of an IC chip. In some embodiments, one or more of the signal pulse generation circuit 330, the one or more measurement devices 340, and the control logic 350 may be provided on a die that is separate from the die on which the quantum circuit component 310 is provided, but in a single IC package.

In some embodiments, the control logic 350 may provide peripheral logic to support the operation of the quantum circuit component 310. For example, the control logic 350 may control the performance of a read operation, control the performance of a write operation, control the clearing of quantum bits, etc., or, in general, control any of the operations described herein with reference to the qubits 312. The control logic 350 may also perform conventional computing functions to supplement the computing functions which may be provided by the quantum circuit component 310. For example, the control logic 350 may interface with one or more of the other components of a quantum computing device, such as e.g. a quantum processing device 2026 shown in FIG. 21, described below, and may serve as an interface between the quantum circuit component 310 and conventional components. In some embodiments, the control logic 350 may be implemented in or may be used to implement a non-quantum processing device 2028, also described below with reference to FIG. 21.

In various embodiments, mechanisms by which the control logic 350 may control operation of the signal pulse generation circuit 330, including implementing active pulse shaping as well as adaptive programming as described herein, may be take the form of an entirely hardware embodiment, an entirely software embodiment (including firmware, resident software, micro-code, etc.) or an embodiment combining software and hardware aspects. For example, the control logic 350 may implement an algorithm executed by one or more processing units, e.g. one or more microprocessors, of one or more computers. In various embodiments, aspects of the present disclosure may take the form of a computer program product embodied in one or more computer readable medium(s), preferably non-transitory, having computer readable program code embodied, e.g., stored, thereon. In various embodiments, such a computer program may, for example, be downloaded (updated) to the control logic 350 or be stored upon manufacturing of the control logic 350.

In some embodiments, as shown in FIG. 14, the control logic 350 may include at least one processor 352 and at least one memory element 354, along with any other suitable hardware and/or software to enable its intended functionality of controlling operation of the signal pulse generation circuit 330 as described herein. The processor 352 can execute software or an algorithm to perform the activities as discussed herein. The processor 352 may be configured to communicatively couple to other system elements via one or more interconnects or buses. Such a processor may include any combination of hardware, software, or firmware providing programmable logic, including by way of non-limiting example a microprocessor, a digital signal processor (DSP), a field-programmable gate array (FPGA), a programmable logic array (PLA), an application specific integrated circuit (ASIC), or a virtual machine processor. The processor 352 may be communicatively coupled to the memory 354, for example in a direct-memory access (DMA) configuration. The memory 354 may include any suitable volatile or non-volatile memory technology, including double data rate (DDR) random access memory (RAM), synchronous RAM (SRAM), dynamic RAM (DRAM), flash, read-only memory (ROM), optical media, virtual memory regions, magnetic or tape memory, or any other suitable technology. Any of the memory items discussed herein should be construed as being encompassed within the broad term “memory element.” The information being tracked or sent to the control logic 350 could be provided in any database, register, control list, cache, or storage structure, all of which can be referenced at any suitable timeframe. Any such storage options may be included within the broad term “memory element” (e.g. the memory 354) of the control logic 350 as used herein. Similarly, any of the potential processing elements, modules, and machines described herein should be construed as being encompassed within the broad term “processor” (e.g. the processor 352) of the control logic 350. The control logic 350 can further include suitable interfaces for receiving, transmitting, and/or otherwise communicating data or information in a network environment.

As described above, the control logic 350 may be configured to receive measurement readings (e.g. current readings) from the one or more measurement devices 340, determine various control parameters based on the measurement readings, and then exercise control over the operation of the signal pulse generation circuit 330 using the determined control parameters, including exercising control of adaptive programming of the signal pulse generation circuit 330. In some embodiments, the control logic 350 may be configured to determine or adjust at least some values of the control parameters applied by the signal pulse generation circuit 330 based on the measurement readings received from the one or more measurement devices 340, e.g., determine or adjust one of more of 1) the frequency of at least one notch of a signal pulse generated by the signal pulse generation circuit 330, 2) the center frequency of a signal pulse generated by the signal pulse generation circuit 330, 3) the bandwidth of a signal pulse generated by the signal pulse generation circuit 330, and 4) the instantaneous phase or frequency of a signal pulse generated by the signal pulse generation circuit 330. In other embodiments, the control logic 350 may be pre-programmed with at least some of the control parameters, e.g. with the values for the bandwidths of signal pulses generated by the signal pulse generation circuit 330.

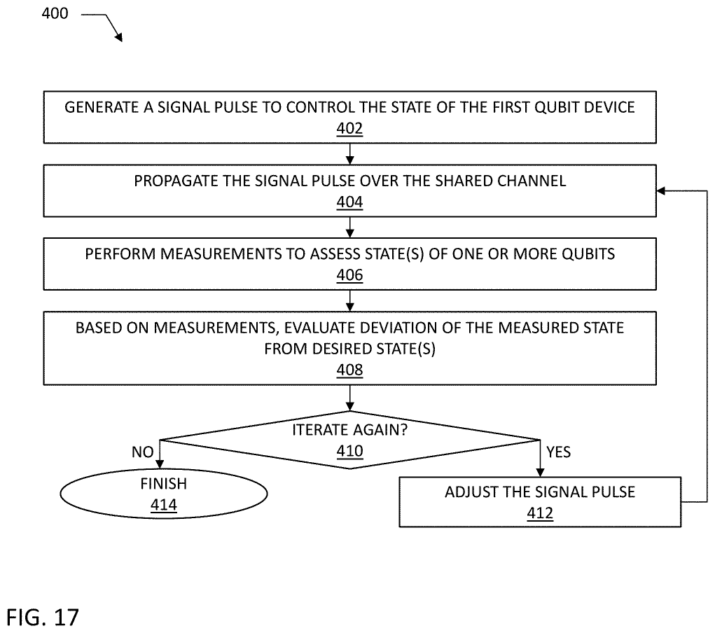

Example operation of the quantum circuit assembly 300 will now be described with reference to FIG. 17, providing a flow diagram of a method 400 for implementing active pulse shaping to control multiple qubits with a shared transmission channel, e.g., with a shared RF transmission line, according to some embodiments of the present disclosure. Although various steps of the method 400 are described with reference to the quantum circuit assembly 300 and are shown in a particular order, any quantum circuit assembly, configured to perform these steps, in any suitable order, is within the scope of the present disclosure.

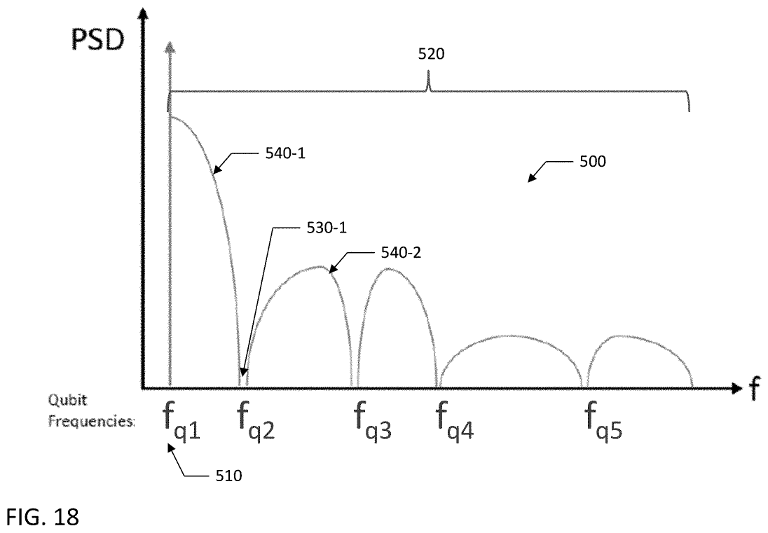

The method 400 may begin with a step 402, which includes the signal pulse generation circuit 330 generating a signal pulse to control the state of the qubit 312-1. To that end, the signal pulse may have a center frequency being substantially equal to a first frequency, f_{q1}, associated with the qubit 312-1 as being the frequency to control the state of the qubit 312-1, and a frequency bandwidth that includes a second frequency, f_{q2}, associated with the qubit 312-2 as being the frequency to control the state of the qubit 312-2. In addition, because the signal pulse generation circuit 330 is configured to implement active pulse shaping to reduce the crosstalk that may arise when a signal pulse configured to control the state of the first qubit 312-1 is provided over the shared transmission channel 320 that is also coupled to the second qubit 312-2, the signal pulse generated at 402 further includes a notch (i.e., a distinct decrease in power spectral density, e.g., more than about 50 dB below the value at the center frequency) at a frequency substantially equal to the second frequency f_{q2}. FIG. 18 provides an example illustration of power spectral density (PSD) as a function of frequency for a shaped pulse 500 that may be used to control a given qubit by being provided over a channel shared with a plurality of other qubits, according to some embodiments of the present disclosure. For example, the pulse 500 may be an example of a signal pulse generated in step 402 when the quantum circuit component 310 includes 5 qubits 312 to which the shared transmission channel 320 is coupled to. In FIG. 18, the frequencies f_{q1}, f_{q2}, f_{q3}, f_{q4}, and f_{q5} are frequencies associated with respective ones of the 5 qubits 312. In FIG. 18, the reference numeral 510 designates the center frequency of the pulse 500, which is the frequency f_{q1} for the example shown, the reference numeral 520 designates the bandwidth of the pulse 500, while the reference numeral 530-1 designates the notch at the frequency associated with the frequency f_{q2} (i.e., the frequency for controlling the second qubit 312-2). Although not specifically labeled in FIG. 18, the pulse 500 also includes notches at the frequencies f_{q3}, f_{q4}, and f_{q5}, associated with controlling qubits 312-3, 312-4, and 312-5, respectively. As is illustrated in FIG. 18, while the signal pulse may have the bandwidth 520 that includes frequencies associated with qubits 312 other than the qubit 312-1, notches 530 are provided at those frequencies, so that the PSD of the signal pulse 500 at those frequencies is significantly below the PSD of the signal pulse 500 at the center frequency 510 (e.g., more than about 50 dB below the value at the center frequency) so that the signal pulse 500 that may be provided to the qubits 312 other than the qubit 312-1 over the shared transmission channel 320 will not substantially affect the states of these other qubits. As also can be seen in FIG. 18, the signal pulse 500 may include a plurality of frequency components at frequencies lower than the frequency of, e.g., the notch 530-1 (e.g., see frequencies in a portion 540-1 of the pulse 500), and having a PSD higher (e.g., at least about 2 times higher or at least about 3 times higher, e.g., at least 2-3 dB higher) than the PSD at the frequency of the notch 530-1. Similarly, the signal pulse 500 may include a plurality of frequency components at frequencies higher than the frequency of, e.g., the notch 530-1 (e.g., see frequencies in a portion 540-2 of the pulse 500), and having a PSD higher (e.g., at least about 2 times higher or at least about 3 times higher, e.g., at least 2-3 dB higher) than the PSD at the frequency of the notch 530-1. Furthermore, in other embodiments, the signal pulse 500 may include further components which are symmetric with respect to the center frequency 510 (i.e., the signal pulse 500 illustrated in FIG. 18 is then only half of the signal pulse, with the other half being symmetric with respect to the center frequency 510).

The method 400 may then proceed with a step 404, which includes propagating the signal pulse generated by the signal pulse generation circuit 330 in step 402 over the shared transmission channel 320. Because the center frequency of the signal pulse being propagated at 404 is substantially at the frequency f_{q1} associated with the qubit 312-1, the signal pulse may be used to control the state of the qubit 312-1. Because the signal pulse has notches at the frequencies of the other qubits 312 also coupled to the shared transmission channel 320, disturbance of the signal pulse on the states of the other qubits 312 may be reduced, minimized, or altogether eliminated.

In some embodiments, the method 400 may conclude with the step 404. In other embodiments, the method 400 may proceed with further steps that implement adaptive programming of the signal pulse generation circuit 330. To that end, the method 400 may include a step 406, which includes performing measurements, e.g., using one or more of the measurement devices 340, to determine a change in the state of one or more other qubits 312 in response to the signal pulse for controlling the state of the first qubit 312-1 being propagated over the shared transmission channel 320. For example, step 406 may include determining a change in the state of the second qubit 312-2 in response to the signal pulse for controlling the state of the first qubit 312-1 being propagated over the shared transmission channel 320. In another example, step 406 may also include determining a change in the state of the first qubit 312-1 in response to the signal pulse for controlling the state of the first qubit 312-1 being propagated over the shared transmission channel 320. To that end, the one or more measurement devices 340 may be configured to measure any suitable measurable parameters (e.g. current, voltage, magnetic field, etc.) indicative of the state of various qubits 312.

The method 400 may further include a step 408, which includes the control logic 350 obtaining information indicative of the measurements performed in step 406, and evaluating deviation of the measured states of one or more qubits 312 from the target/desired states of these qubits. For example, 408 may include determining whether propagation of the signal pulse generated in 402 achieved the first qubit 312-1 being set to the desired state. In another example, 408 may include determining whether propagation of the signal pulse generated in 402 achieved the goal of reducing or eliminating the disturbance of the states of one or more of qubits 312 other than the first qubit 312-1. In some embodiments, step 408 may include the control logic 350 computing one or more parameters indicative of the state(s) of the qubits 312 based on the measurements of the step 406, and assessing whether the measured states deviate from the desired states. For example, in some embodiments, the control logic 350 may be configured to implement a randomized benchmarking experiment to measure the fidelity of gate operations on the first qubit 312-1 and then measure the state of the other qubits 312 initially reset to ground state to verify that their state has not been perturbed by cross-talk from the pulses targeted to qubit 312-1.

The method 400 may further include a step 410, which includes the control logic 350 determining whether to send another signal pulse to achieve the desired states for one or more qubits 312. If so, then the method 400 may proceed a step 412, which includes the control logic 350 adjusting one or more parameters of a signal pulse to be generated by the signal pulse generation circuit 330, and the method 400 proceeding to the step 402 where the signal pulse generation circuit 330 generates a signal pulse again, but now with the one or more parameters that have been adjusted by the control logic 350 in step 412. Otherwise, the method 400 may finish, in step 414. In some embodiments, one or more parameters that may be adjusted by the control logic 350 in step 412 may include one or more of the frequency of the one or more notches of the signal pulse, the center frequency of the signal pulse, the bandwidth of the signal pulse, and the instantaneous phase or frequency of the signal pulse.

Various embodiments may be envisioned as to how the control logic 350 may be configured to determine, in step 410, whether to iterate the sequence of steps 402-408 with the one or more parameters of the signal pulse adjusted in step 414. In some embodiments, the control logic 350 may be configured to perform the adjustment of the parameters of the pulse 414 and iteration of the sequence of steps 402-408 a predefined number of times. In some embodiments, the control logic 350 may be configured to perform the adjustment of the parameters of the pulse 414 and iteration of the sequence of steps 402-408 until the measured change in the states of one or more qubits 312 satisfies one or more criteria. For example, the control logic 350 may be configured to perform the adjustment of the parameters of the pulse 414 and iteration of the sequence of steps 402-408 until the measured change in the state of the second qubit 312-2 satisfies at least one criterion, such as the change in the state of the second qubit 312-2 in response to the signal pulse being propagated over the shared transmission channel 320 to control the first qubit 312-1 being within a certain tolerance. In various embodiments, the one or more criteria taking into consideration by the control logic 350 to make a decision in step 410 may be predefined (e.g., previously set, preprogrammed into the control logic 350, or stored in memory, e.g., the memory 354, and accessible by the control logic 350) or dynamically defined (e.g. the control logic 350 may be configured to determine what the criteria should be based on some operating parameters of the quantum circuit component 310).

The method 400 may be performed when signal pulses for controlling various ones of the qubits 312 are to be propagated over the shared transmission channel 320 in a way that reduces, minimizes, or avoids disturbance of the other qubits 312. In various embodiments, such signal pulses may be propagated over the shared transmission channel 320 at different times, or they may at least partially or fully overlap at certain times. For example, in some embodiments, one signal pulse may be transmitted over the shared transmission channel 320 to control the state of the first qubit 312-1, while at the same time another signal pulse may be transmitted over the shared transmission channel 320 to control the state of the second qubit 312-2. The signal pulse for controlling the state of the first qubit 312-1 may be actively shaped to reduce, minimize, or avoid disturbance of the second qubit 312-2 according to any embodiments described herein, while the signal pulse for controlling the state of the second qubit 312-2 may be actively shaped to reduce, minimize, or avoid disturbance of the first qubit 312-1 according to any embodiments described herein. Thus, in some embodiments, the shared transmission channel 320 may be configured to support propagation of a superposition of signal pulses for controlling different qubits 312.

### Example Devices and Systems

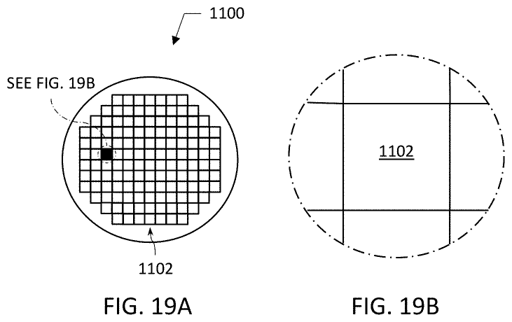

Quantum circuit assemblies configured to implement active pulse shaping to control multiple qubits with a shared transmission channel as described above may be implemented using any kind of qubit devices or be included in any kind of quantum processing devices/structures. Some examples of such devices/structures are illustrated in FIGS. 19A-19B, 20, and 21.

FIGS. 19A-19B are top views of a wafer 1100 and dies 1102 that may be formed from the wafer 1100, according to some embodiments of the present disclosure. The dies 1102 may include any of the qubit devices disclosed herein, e.g. the qubit devices described with reference to FIGS. 1-15, any further embodiments of such qubit devices as described herein, or any combinations of such qubit devices. The wafer 1100 may include semiconductor material and may include one or more dies 1102 having conventional and quantum circuit device elements formed on a surface of the wafer 1100. Each of the dies 1102 may be a repeating unit of a semiconductor product that includes any suitable conventional and/or quantum circuit qubit device. After the fabrication of the semiconductor product is complete, the wafer 1100 may undergo a singulation process in which each of the dies 1102 is separated from one another to provide discrete “chips” of the semiconductor product. A die 1102 may include, or be included in, a quantum circuit component, e.g. the quantum circuit component 310 as described herein. In some embodiments, the wafer 1100 or the die 1102 may include a memory device (e.g., a static random access memory (SRAM) device), a logic device (e.g., AND, OR, NAND, or NOR gate), or any other suitable circuit element. Multiple ones of these devices may be combined on a single die 1102. For example, a memory array formed by multiple memory devices may be formed on a same die 1102 as a processing device (e.g., the processing device 2002 of FIG. 21) or other logic that is configured to store information in the memory devices or execute instructions stored in the memory array.

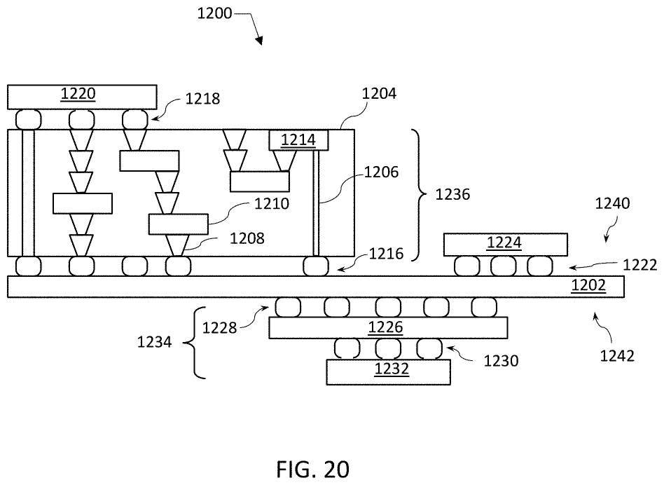

FIG. 20 is a cross-sectional side view of a device assembly 1200 that may be included in any of the embodiments of the quantum circuit assemblies disclosed herein. The device assembly 1200 includes a number of components disposed on a circuit board 1202. The device assembly 1200 may include components disposed on a first face 1240 of the circuit board 1202 and an opposing second face 1242 of the circuit board 1202; generally, components may be disposed on one or both faces 1240 and 1242.

In some embodiments, the circuit board 1202 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1202. In other embodiments, the circuit board 1202 may be a package substrate or flexible board.

The IC device assembly 1200 illustrated in FIG. 20 may include a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 20), male and female portions of a socket, an adhesive, an underfill material, and/or any other suitable electrical and/or mechanical coupling structure.

The package-on-interposer structure 1236 may include a package 1220 coupled to an interposer 1204 by coupling components 1218. The coupling components 1218 may take any suitable form for the application, such as the forms discussed above with reference to the coupling components 1216. Although a single package 1220 is shown in FIG. 20, multiple packages may be coupled to the interposer 1204; indeed, additional interposers may be coupled to the interposer 1204. The interposer 1204 may provide an intervening substrate used to bridge the circuit board 1202 and the package 1220. The package 1220 may be a quantum circuit device package as described herein, e.g. a package including any of the quantum circuit assemblies configured to implement active pulse shaping to control multiple qubits with a shared transmission channel, any further embodiments of such quantum circuit assemblies as described herein, or any combinations of such quantum circuit assemblies; or may be a conventional IC package, for example. Generally, the interposer 1204 may spread a connection to a wider pitch or reroute a connection to a different connection. For example, the interposer 1204 may couple the package 1220 (e.g., a die) to a ball grid array (BGA) of the coupling components 1216 for coupling to the circuit board 1202. In the embodiment illustrated in FIG. 20, the package 1220 and the circuit board 1202 are attached to opposing sides of the interposer 1204; in other embodiments, the package 1220 and the circuit board 1202 may be attached to a same side of the interposer 1204. In some embodiments, three or more components may be interconnected by way of the interposer 1204.

The interposer 1204 may be formed of an epoxy resin, a fiberglass-reinforced epoxy resin, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through-silicon vias (TSVs) 1206. The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The device assembly 1200 may include a package 1224 coupled to the first face 1240 of the circuit board 1202 by coupling components 1222. The coupling components 1222 may take the form of any of the embodiments discussed above with reference to the coupling components 1216, and the package 1224 may take the form of any of the embodiments discussed above with reference to the package 1220. The package 1224 may be a package including any quantum circuit assemblies configured to implement active pulse shaping to control multiple qubits with a shared transmission channel disclosed herein, any further embodiments of such quantum circuit assemblies as described herein, or any combinations of such quantum circuit assemblies; or may be a conventional IC package, for example.

The device assembly 1200 illustrated in FIG. 20 includes a package-on-package structure 1234 coupled to the second face 1242 of the circuit board 1202 by coupling components 1228. The package-on-package structure 1234 may include a package 1226 and a package 1232 coupled together by coupling components 1230 such that the package 1226 is disposed between the circuit board 1202 and the package 1232. The coupling components 1228 and 1230 may take the form of any of the embodiments of the coupling components 1216 discussed above, and the packages 1226 and 1232 may take the form of any of the embodiments of the package 1220 discussed above. Each of the packages 1226 and 1232 may be a qubit device package as described herein or may be a conventional IC package, for example.

FIG. 21 is a block diagram of an example quantum computing device 2000 that may include any of the quantum circuit assemblies configured to implement active pulse shaping to control multiple qubits with a shared transmission channel as disclosed herein, or any combinations of such quantum circuit assemblies. Several components are illustrated in FIG. 21 as included in the quantum computing device 2000, but any one or more of these components may be omitted or duplicated, as suitable for the application. In some embodiments, some or all of the components included in the quantum computing device 2000 may be attached to one or more PCBs (e.g., a motherboard), and may be included in, or include, any of the quantum circuits with any of the quantum circuit assemblies described herein. In some embodiments, various ones of these components may be fabricated onto a single system-on-a-chip (SoC) die. Additionally, in various embodiments, the quantum computing device 2000 may not include one or more of the components illustrated in FIG. 21, but the quantum computing device 2000 may include interface circuitry for coupling to the one or more components. For example, the quantum computing device 2000 may not include a display device 2006, but may include display device interface circuitry (e.g., a connector and driver circuitry) to which a display device 2006 may be coupled. In another set of examples, the quantum computing device 2000 may not include an audio input device 2018 or an audio output device 2008, but may include audio input or output device interface circuitry (e.g., connectors and supporting circuitry) to which an audio input device 2018 or audio output device 2008 may be coupled.

The quantum computing device 2000 may include a cooling apparatus 2024. The cooling apparatus 2024 may maintain a quantum processing device 2026 of the quantum computing device 2000, in particular the qubit devices as described herein, at a predetermined low temperature during operation to avoid qubit decoherence and to reduce the effects of scattering in the quantum processing device 2026. In some embodiments, a non-quantum processing device 2028 of the quantum computing device 2000 (and various other components of the quantum computing device 2000) may not be cooled by the cooling apparatus 2030 and may instead operate at room temperature.

The quantum computing device 2000 may include a processing device 2002 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2002 may include a quantum processing device 2026 (e.g., one or more quantum processing devices), and a non-quantum processing device 2028 (e.g., one or more non-quantum processing devices). The quantum processing device 2026 may include any of the quantum circuit assemblies configured to implement active pulse shaping to control multiple qubits with a shared transmission channel as disclosed herein, and may perform data processing by performing operations on the qubits that may be generated in the quantum circuit components 310, and monitoring the result of those operations. For example, as discussed above, different qubits may be allowed to interact, the quantum states of different qubits may be set or transformed, and the quantum states of different qubits may be read. The quantum processing device 2026 may be a universal quantum processor, or specialized quantum processor configured to run one or more quantum algorithms. In some embodiments, the quantum processing device 2026 may execute algorithms that are particularly suitable for quantum computers, such as cryptographic algorithms that utilize prime factorization, encryption/decryption, algorithms to optimize chemical reactions, algorithms to model protein folding, etc. The quantum processing device 2026 may also include support circuitry to support the processing capability of the quantum processing device 2026, such as input/output channels, multiplexers, signal mixers, quantum amplifiers, and analog-to-digital converters.

As noted above, the processing device 2002 may include a non-quantum processing device 2028. In some embodiments, the non-quantum processing device 2028 may provide peripheral logic to support the operation of the quantum processing device 2026. For example, the non-quantum processing device 2028 may control the performance of a read operation, control the performance of a write operation, control the clearing of quantum bits, etc. The non-quantum processing device 2028 may also perform conventional computing functions to supplement the computing functions provided by the quantum processing device 2026. For example, the non-quantum processing device 2028 may interface with one or more of the other components of the quantum computing device 2000 (e.g., the communication chip 2012 discussed below, the display device 2006 discussed below, etc.) in a conventional manner, and may serve as an interface between the quantum processing device 2026 and conventional components. The non-quantum processing device 2028 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

The quantum computing device 2000 may include a memory 2004, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, the states of qubits in the quantum processing device 2026 may be read and stored in the memory 2004. In some embodiments, the memory 2004 may include memory that shares a die with the non-quantum processing device 2028. This memory may be used as cache memory and may include embedded dynamic random-access memory (eDRAM) or spin transfer torque magnetic random-access memory (STT-M RAM).

In some embodiments, the quantum computing device 2000 may include a communication chip 2012 (e.g., one or more communication chips). For example, the communication chip 2012 may be configured for managing wireless communications for the transfer of data to and from the quantum computing device 2000. The term “wireless” and its derivatives may be used to describe circuits, devices, systems, methods, techniques, communications channels, etc., that may communicate data using modulated electromagnetic radiation through a nonsolid medium. The term does not imply that the associated devices do not contain any wires, although in some embodiments they might not.

The communication chip 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2012 may operate in accordance with other wireless protocols in other embodiments. The quantum computing device 2000 may include an antenna 2022 to facilitate wireless communications and/or to receive other wireless communications (such as AM or FM radio transmissions).

In some embodiments, the communication chip 2012 may manage wired communications, such as electrical, optical, or any other suitable communication protocols (e.g., the Ethernet). As noted above, the communication chip 2012 may include multiple communication chips. For instance, a first communication chip 2012 may be dedicated to shorter-range wireless communications such as Wi-Fi or Bluetooth, and a second communication chip 2012 may be dedicated to longer-range wireless communications such as global positioning system (GPS), EDGE, GPRS, CDMA, WiMAX, LTE, EV-DO, or others. In some embodiments, a first communication chip 2012 may be dedicated to wireless communications, and a second communication chip 2012 may be dedicated to wired communications.

The quantum computing device 2000 may include battery/power circuitry 2014. The battery/power circuitry 2014 may include one or more energy storage devices (e.g., batteries or capacitors) and/or circuitry for coupling components of the quantum computing device 2000 to an energy source separate from the quantum computing device 2000 (e.g., AC line power).

The quantum computing device 2000 may include a display device 2006 (or corresponding interface circuitry, as discussed above). The display device 2006 may include any visual indicators, such as a heads-up display, a computer monitor, a projector, a touchscreen display, a liquid crystal display (LCD), a light-emitting diode display, or a flat panel display, for example.

The quantum computing device 2000 may include an audio output device 2008 (or corresponding interface circuitry, as discussed above). The audio output device 2008 may include any device that generates an audible indicator, such as speakers, headsets, or earbuds, for example.

The quantum computing device 2000 may include an audio input device 2018 (or corresponding interface circuitry, as discussed above). The audio input device 2018 may include any device that generates a signal representative of a sound, such as microphones, microphone arrays, or digital instruments (e.g., instruments having a musical instrument digital interface (MIDI) output).

The quantum computing device 2000 may include a GPS device 2016 (or corresponding interface circuitry, as discussed above). The GPS device 2016 may be in communication with a satellite-based system and may receive a location of the quantum computing device 2000, as known in the art.

The quantum computing device 2000 may include an other output device 2010 (or corresponding interface circuitry, as discussed above). Examples of the other output device 2010 may include an audio codec, a video codec, a printer, a wired or wireless transmitter for providing information to other devices, or an additional storage device.

The quantum computing device 2000 may include an other input device 2020 (or corresponding interface circuitry, as discussed above). Examples of the other input device 2020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The quantum computing device 2000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

### SELECT EXAMPLES

The following paragraphs provide examples of various ones of the embodiments disclosed herein.

Example 1 provides a quantum circuit assembly that includes a quantum circuit component having a first qubit device, associated with a first frequency to be used to control a state of the first qubit device, and a second qubit device, associated with a second frequency to be used to control a state of the second qubit device. The quantum circuit assembly further includes a shared transmission channel (e.g., an RF transmission line), coupled to each of the first qubit device and the second qubit device, and configured to support propagation of signal pulses configured to control the state of the first qubit device and the state of the second qubit device. The quantum circuit assembly also includes a signal pulse generation circuit, configured to generate a signal pulse to be propagated over the shared transmission channel to control the state of the first qubit device, the signal pulse having a center frequency being substantially equal to the first frequency, a frequency bandwidth that includes the second frequency, and a notch (i.e., a distinct decrease in power spectral density, e.g., more than about 20 dB, or more than about 30 dB, or more than about 50 dB below the value at the center frequency) at a frequency substantially equal to the second frequency.

Example 2 provides the quantum circuit assembly according to example 1, where the signal pulse has a plurality of frequency components at frequencies lower than the frequency of the notch and having a power spectral density higher (e.g., at least about 2 times higher or at least about 3 times higher, e.g., at least 2-3 dB higher) than a power spectral density at the frequency of the notch.

Example 3 provides the quantum circuit assembly according to examples 1 or 2, where the signal pulse has a plurality of frequency components at frequencies higher than the frequency of the notch and having a power spectral density higher (e.g., at least about 2 times higher or at least about 3 times higher, e.g., at least 2-3 dB higher) than a power spectral density at the frequency of the notch.

Example 4 provides the quantum circuit assembly according to any one of the preceding examples, where the quantum circuit component further includes a third qubit device, associated with a third frequency to be used to control a state of the third qubit device, the shared transmission channel is further configured to support propagation of signal pulses configured to control the state of the third qubit device, the bandwidth of the signal pulse includes the third frequency, and the signal pulse has a further notch at a frequency substantially equal to the third frequency.

Example 5 provides the quantum circuit assembly according to any one of the preceding examples, further including a control logic, configured to obtain a measure of a change in the state of the second qubit device in response to the signal pulse being propagated over the shared transmission channel, and adjust at least one parameter of the signal pulse (e.g., the frequency of the notch, the center frequency, the bandwidth, the overall phase response, etc.) based on the measure of the change in the state of the second qubit device, so that the next time the signal pulse is propagated over the shared transmission channel to control the state of the first qubit the signal pulse is a signal pulse with one or more adjusted parameters.

Example 6 provides the quantum circuit assembly according to example 5, where the at least one parameter of the signal pulse adjusted by the control logic include one or more of the frequency of the notch, the center frequency, the bandwidth, and a phase response of the signal pulse.

Example 7 provides the quantum circuit assembly according to examples 5 or 6, where the control logic is configured to iterate a sequence of obtaining the measure of the change in the state of the second qubit device and adjusting the at least one parameter of the signal pulse two or more times to reduce the change in the state of the second qubit device in response to the signal pulse being propagated over the shared transmission channel.

Example 8 provides the quantum circuit assembly according to example 7, where iterating the sequence two or more times includes iterating the sequence a predefined number of times.

Example 9 provides the quantum circuit assembly according to example 7, where iterating the sequence two or more times includes iterating the sequence until the measured change in the state of the second qubit device satisfies at least one criterion.

Example 10 provides the quantum circuit assembly according to example 9, where the at least one criterion includes the change in the state of the second qubit device in response to the signal pulse being propagated over the shared transmission channel being within a tolerance

Example 11 provides the quantum circuit assembly according to examples 9 or 10, where the at least one criterion is predefined (e.g. previously set, preprogrammed into the control logic, or stored in memory and accessible by the control logic).

Example 12 provides the quantum circuit assembly according to examples 9 or 10, where the at least one criterion is dynamically defined (e.g. the control logic is configured to determine what the at least one criterion should be based on some operating parameters).

Example 13 provides the quantum circuit assembly according to any one of examples 5-12, where the quantum circuit component and the control logic are provided in a single IC package.

Example 14 provides the quantum circuit assembly according to any one of examples 5-13, where the quantum circuit component and the control logic are provided on a single die.

Example 15 provides the quantum circuit assembly according to any one of examples 1-14, where the first qubit device and the second qubit device are superconducting qubit devices.

Example 16 provides the quantum circuit assembly according to any one of examples 1-14, where the first qubit device and the second qubit device are quantum dot qubit devices.

Example 17 provides a quantum circuit assembly, including a quantum circuit component that includes a first qubit device, associated with a first frequency to be used to control a state of the first qubit device, and a second qubit device, associated with a second frequency to be used to control a state of the second qubit device; a shared signal propagation channel, coupled to each of the first qubit device and the second qubit device, and configured to support propagation of signal pulses configured to control the state of the first qubit device and the state of the second qubit device; and a signal pulse generation circuit, configured to generate a signal pulse to be propagated over the signal propagation channel to control the state of the first qubit device, the signal pulse having a center frequency being substantially equal to the first frequency, a frequency bandwidth that is greater than about twice a difference between the second frequency and the first frequency, and a notch at a frequency substantially equal to the second frequency.

Example 18 provides the quantum circuit assembly according to example 17, where the signal propagation channel is a waveguide and the signal pulse is an optical pulse.

In other examples, the signal propagation channel may be an RF transmission line and the quantum circuit assembly according to example 17 may be the quantum circuit assembly according to any one of examples 1-16.

In still other examples, the signal propagation channel may be free space and the signal pulses may be either RF (e.g., microwave) or optical signal pulses, configured to control the state of the first qubit device and the state of the second qubit device by free space propagation.

Example 19 provides a method of operating a quantum circuit assembly that includes a signal propagation channel and a quantum circuit component having a first qubit device, associated with a first frequency to be used to control a state of the first qubit device, and further having a second qubit device, associated with a second frequency to be used to control a state of the second qubit device. The method includes propagating a signal pulse over the signal propagation channel coupled to each of the first qubit device and the second qubit device, the signal pulse having a center frequency being substantially equal to the first frequency, a frequency bandwidth that includes the second frequency, and a notch at a frequency substantially equal to the second frequency. The method also includes obtaining a measure of a change in the state of the second qubit device in response to the signal pulse being propagated over the signal propagation channel and adjusting at least one parameter of the signal pulse (e.g., the frequency of the notch, the center frequency, the bandwidth, the instantaneous frequency or phase, etc.) based on the measure of the change in the state of the second qubit device to generate an adjusted signal pulse. The method further includes propagating the adjusted signal pulse over the signal propagation channel.

Example 20 provides the method according to example 19, where the signal propagation channel is free space. In some methods according to example 20, the signal pulses propagating in free space may be either RF (e.g., microwave) or optical signal pulses.

Example 21 provides the method according to example 19, where the signal propagation channel is an RF transmission line (e.g., an RF/microwave transmission line) or an optical transmission line.

Example 22 provides the method according to any one of examples 19-21, where the quantum circuit assembly is the quantum circuit assembly according to any one of examples 1-16 or the quantum circuit assembly according to any one of examples 17-18.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A quantum circuit assembly, comprising:
a quantum circuit component that includes:
a first qubit device, associated with a first frequency to control a state of the first qubit device, and
a second qubit device, associated with a second frequency to control a state of the second qubit device;
a shared transmission channel, configured to support propagation of signal pulses configured to control the state of the first qubit device and the state of the second qubit device; and
a signal pulse generation circuit, configured to generate a signal pulse to be propagated over the shared transmission channel to control the state of the first qubit device, the signal pulse having:
a center frequency being substantially equal to the first frequency,
a bandwidth that includes the second frequency, and
a notch at a frequency substantially equal to the second frequency.

2. The quantum circuit assembly according to claim 1, wherein the signal pulse has a plurality of frequency components at frequencies lower than the frequency of the notch and having a power spectral density higher than a power spectral density at the frequency of the notch.

3. The quantum circuit assembly according to claim 1, wherein the signal pulse has a plurality of frequency components at frequencies higher than the frequency of the notch and having a power spectral density higher than a power spectral density at the frequency of the notch.

4. The quantum circuit assembly according to claim 1, wherein:
the quantum circuit component further includes a third qubit device, associated with a third frequency to be used to control a state of the third qubit device,
the shared transmission channel is further configured to support propagation of signal pulses configured to control the state of the third qubit device,
the bandwidth of the signal pulse includes the third frequency, and
the signal pulse has a further notch at a frequency substantially equal to the third frequency.

5. The quantum circuit assembly according to claim 1, further comprising a control logic, configured to:
obtain a measure of a change in the state of the second qubit device in response to the signal pulse being propagated over the shared transmission channel, and
adjust at least one parameter of the signal pulse based on the measure of the change in the state of the second qubit device.

6. The quantum circuit assembly according to claim 5, wherein the at least one parameter of the signal pulse includes one or more of: the frequency of the notch, the center frequency, the bandwidth, and a phase response of the signal pulse.

7. The quantum circuit assembly according to claim 5, wherein the control logic is configured to iterate a sequence of obtaining the measure of the change in the state of the second qubit device and adjusting the at least one parameter of the signal pulse two or more times.

8. The quantum circuit assembly according to claim 7, wherein iterating the sequence two or more times includes iterating the sequence a predefined number of times.

9. The quantum circuit assembly according to claim 7, wherein iterating the sequence two or more times includes iterating the sequence until the change in the state of the second qubit device satisfies at least one criterion.

10. The quantum circuit assembly according to claim 9, wherein the at least one criterion includes the change in the state of the second qubit device in response to the signal pulse being propagated over the shared transmission channel being within a tolerance.

11. The quantum circuit assembly according to claim 9, wherein the at least one criterion is predefined.

12. The quantum circuit assembly according to claim 9, wherein the at least one criterion is dynamically defined.

13. The quantum circuit assembly according to claim 5, wherein the quantum circuit component and the control logic are provided in a single integrated circuit (IC) package.

14. The quantum circuit assembly according to claim 5, wherein the quantum circuit component and the control logic are provided on a single die.

15. The quantum circuit assembly according to claim 1, wherein the first qubit device and the second qubit device are superconducting qubit devices.

16. The quantum circuit assembly according to claim 1, wherein the first qubit device and the second qubit device are quantum dot qubit devices.

17. A quantum circuit assembly, comprising:
a quantum circuit component that includes:
a first qubit device, associated with a first frequency to be used to control a state of the first qubit device, and
a second qubit device, associated with a second frequency to be used to control a state of the second qubit device;
a signal propagation channel, configured to support propagation of signal pulses configured to control the state of the first qubit device and the state of the second qubit device; and
a signal pulse generation circuit, configured to generate a signal pulse to be propagated over the signal propagation channel to control the state of the first qubit device, the signal pulse having:
a center frequency being substantially equal to the first frequency,
a bandwidth that is greater than about twice a difference between the second frequency and the first frequency, and
a notch at a frequency substantially equal to the second frequency.

18. The quantum circuit assembly according to claim 17, wherein the signal propagation channel is a waveguide and the signal pulse is an optical pulse.

19. A method of operating a quantum circuit assembly that includes a signal propagation channel and a quantum circuit component having a first qubit device, associated with a first frequency to be used to control a state of the first qubit device, and further having a second qubit device, associated with a second frequency to be used to control a state of the second qubit device, the method comprising:
propagating a signal pulse over the signal propagation channel coupled to each of the first qubit device and the second qubit device, the signal pulse having:
a center frequency being substantially equal to the first frequency,
a bandwidth that includes the second frequency, and
a notch at a frequency substantially equal to the second frequency;
obtaining a measure of a change in the state of the second qubit device in response to the signal pulse being propagated over the signal propagation channel;
adjusting at least one parameter of the signal pulse based on the measure of the change in the state of the second qubit device to generate an adjusted signal pulse; and
propagating the adjusted signal pulse over the signal propagation channel.

20. The method according to claim 19, wherein the signal propagation channel is free space.
